(19) United States
(12) Patent Application Publication
(10) Pub. No.: US 2011/0217852 A1
(43) Pub. Date: Sep. 8, 2011

(54) SUBSTRATE PROCESSING APPARATUS AND METHOD OF MANUFACTURING SEMICONDUCTOR DEVICE

(75) Inventors: Kenichi SUZAKI, Toyama (JP); Takuya JODA, Toyama (JP)

(73) Assignee: HITACHI KOKUSAI ELECTRIC INC., Tokyo (JP)

(21) Appl. No.: 13/039,816

(22) Filed: Mar. 3, 2011

(30) Foreign Application Priority Data
Mar. 5, 2010 (JP) 2010-049229

(51) Int. Cl. H01L 21/324; H05B 6/02

(52) U.S. Cl. 438/795; 219/647; 257/E21.328

(57) ABSTRACT

Provided is technology for preventing breakage of an induction target part of a substrate processing apparatus using an induction heating method. The substrate processing apparatus including a reaction vessel configured to process a substrate therein; a first induction target part comprising a peripheral portion and a center portion wherein a thickness of the center portion is less than that of the peripheral portion, the first induction target part being configured to heat the substrate accommodated on the center portion; a second induction target part comprising a peripheral portion and a center portion wherein a thickness of the center portion is equal to or greater than that of the peripheral portion, the second induction target part being configured to heat the substrate accommodated on the center portion of the first induction target part; an induction target part holder configured to hold the first induction target part and the second induction target part in a manner that the second induction part is spaced apart from the first induction target part by a predetermined distance; and an induction heating device configured to heat at least the first and second induction target parts in the reaction vessel held by the induction target part holder using an induction heating method.

### CROSS-REFERENCE TO RELATED PATENT APPLICATION

This U.S. non-provisional patent application claims priority under 35 U.S.C. §119 of Japanese Patent Application No. 2010-049229, filed on Mar. 5, 2010, in the Japanese Patent Office, the entire contents of which are hereby incorporated by reference.

### BACKGROUND OF THE INVENTION

1. Field of the Invention

The present invention relates to a substrate processing apparatus and a method of manufacturing a semiconductor device.

2. Description of the Related Art

In the related art, hot wall type chemical vapor deposition (CVD) apparatuses are widely used as substrate processing apparatuses. A reaction furnace is made of a quartz member, and a resistance heating method is used to heat the reaction furnace. When heating the reaction furnace, the reaction furnace is entirely heated, and the inside temperature of the reaction furnace is controlled by using a control unit. A source gas is supplied through a device such as a supply nozzle to form a film on a substrate (for example, refer to Patent Document 1).

[Patent Document 1] Japanese Unexamined Patent Application Publication No. 2008-277785

As described above, as an example of a substrate processing apparatus, there is a substrate processing apparatus using a resistance heating method. In the substrate processing apparatus using a resistance heating method, for example, a resistance wire is wound in a coil shape around the outer surface of a cylindrical reaction furnace, and if a current is applied to the resistance wire, Joule heat is generated to heat the entire area of the reaction furnace. In the above-described substrate processing apparatus using the resistance heating method, not only a semiconductor substrate disposed in the reaction furnace but also the reaction furnace is heated. Therefore, if a source gas is supplied into the reaction furnace through a supply nozzle in a state where the reaction furnace is heated, a film is formed on the inner wall of the heated reaction furnace as well as on the semiconductor substrate. In this case, contaminants may be generated as the film formed on the inner wall of the reaction furnace is stripped, and particles of the stripped film adhere to the semiconductor substrate. Thus, the semiconductor device manufacturing yield may be decreased.

For this reason, the use of a substrate processing apparatus using an induction heating method is underway, particular, for the case of forming a thick film. In the substrate processing apparatus using an induction heating method, a high-frequency coil is installed around the outer surface of a reaction furnace. High-frequency power is applied to the high-frequency coil to induce eddy currents in an induction target part disposed in the reaction furnace for heating the induction target part by using the eddy currents. In detail, an induction target part in which eddy currents can be efficiently generated by applying high-frequency power to the high-frequency coil is installed in the reaction furnace, and a semiconductor substrate is disposed on the induction target part. Then, the induction target part is first heated by eddy currents generated in the induction target part, and the semiconductor substrate disposed on the induction target part is then heated by heat conduction. If a source gas is supplied into the reaction furnace through a supply nozzle in a state where the semiconductor substrate is heated in this way, a film can be formed on the heated semiconductor substrate.

In the substrate processing apparatus using the induction heating method, the induction target part disposed in the reaction furnace is heated by applying high-frequency power to the high-frequency coil installed around the outer surface of the reaction furnace. Therefore, the inner wall of the reaction furnace itself is not much heated. Therefore, when a source gas is supplied into the reaction furnace, although a film can be formed on the high-temperature semiconductor substrate, a film may not be easily formed on the low-temperature inner wall of the reaction furnace. For this reason, in the substrate processing apparatus using the induction heating method, a film is not easily formed on the inner wall of the reaction furnace, and thus generation of contaminants from the inner wall of the reaction furnace and adherence of film particles to the semiconductor substrate can be prevented. That is, the substrate processing apparatus using the induction heating method is characterized in that the inner wall of the reaction furnace is not easily heated and a film does not easily adhere to the inner wall of the reaction furnace as compared with a substrate processing apparatus using a resistance heating method. Therefore, a decrease of semiconductor device manufacturing yield caused by generation of contaminants can be surely suppressed by using the substrate processing apparatus employing the induction heating method as compared with the case of using a substrate processing apparatus employing a resistance heating method.

As one of such advantageous substrate processing apparatuses using the induction heating method, there is a substrate processing apparatus configured to form films on a plurality of substrates. The substrate processing apparatus includes: a reaction vessel (reaction furnace) configured to process substrates therein; induction target parts each having a center portion thinner than a peripheral portion to heat a semiconductor substrate accommodated in the center portion; and an induction target part holder configured to hold the induction target parts at predetermined intervals in the extending direction of the reaction vessel. That is, a plurality of induction target parts are disposed on the induction target part holder, and semiconductor substrates are loaded on the plurality of induction target parts, respectively. In this case, although the peripheral portions of the induction target parts can be kept at a constant temperature owing to eddy currents, the center portions of the induction target parts are difficult to be heated by eddy currents because eddy currents are not easily generated in the center portions. The temperature of the center portion of an induction target part is determined by the balance among heat conduction from the peripheral portion of the induction target part heated by eddy currents, heat radiation from the upper and lower induction target parts, and heat release at the center portion of the induction target part. If there are upper and lower induction target parts adjacent to the induction target part, since heat release from the center portion of the induction target part can be suppressed, the temperature difference between the peripheral portion and the center portion of the induction target part is not so great.

However, in the case of an induction target part disposed on the uppermost or lowermost stage above or under which no induction target part exists, the amount of heat released from the center portion of the induction target part is greater than the amount of heat conducted from the peripheral portion of the induction target part. In addition, since there is no upper or lower induction target part, the amount of heat radiation from a neighboring induction target part is also low. Therefore, in the case of the induction target part disposed on the uppermost or lowermost stage, the temperature of the center portion is considerably lower than the temperature of the peripheral portion. In addition, since a semiconductor substrate is loaded on the center portion of an induction target part, the center portion of the induction target part is thinner than the peripheral portion of the induction target part. As a result, in the case of the induction target part disposed on the uppermost or lowermost stage, stress may easily be concentrated on a stepped part between the peripheral portion and the center portion due to a temperature difference between the peripheral portion and the center portion. If stress is concentrated in this way, there may be problems such as breakage of the induction target part disposed on the uppermost or lowermost stage. In addition, although there is an upper or lower induction target part, if there is a considerable distance from the uppermost or lowermost induction target part to the induction target parts held by the induction target part holder at predetermined intervals in the extending direction of the reaction vessel, for example, if the considerable distance is three times the predetermined intervals, there may be the same problems as those mentioned above. In addition, although there is an upper or lower induction target part, if there is a considerable distance from one or more induction target parts held by the induction target part holder, the same problems as those mentioned above may occur.

### SUMMARY OF THE INVENTION

An object of the present invention is to provide technology for preventing breakage of an induction target part of a substrate processing apparatus using an induction heating method.

The object, other objects, and features of the present invention will be apparent from the description of the specification and the attached drawings.

The following is a brief description of the gist of the representative elements of the invention disclosed in this application.

An object of the present invention is to provide a substrate processing apparatus including: a reaction vessel configured to process a substrate therein; a first induction target part including a peripheral portion and a center portion wherein a thickness of the center portion is less than that of the peripheral portion, the first induction target part being configured to heat the substrate accommodated on the center portion; a second induction target part including a peripheral portion and a center portion wherein a thickness of the center portion is equal to or greater than that of the peripheral portion, the second induction target part being configured to heat the substrate accommodated on the center portion of the first induction target part; an induction target part holder configured to hold the first induction target part and the second induction target part in a manner that the second induction part is spaced apart from the first induction target part by a predetermined distance; and an induction heating device configured to heat at least the first and second induction target parts in the reaction vessel held by the induction target part holder using an induction heating method.

### BRIEF DESCRIPTION OF THE DRAWINGS

FIG. 1 is a schematic view illustrating a substrate processing apparatus according to Embodiment 1 of the present invention.

FIG. 2 is a top view illustrating a state where a wafer is held on a susceptor.

FIG. 3 is a sectional view taken along line A-A of FIG. 2.

FIG. 4 is a sectional view illustrating a state where the wafer is separated from the susceptor.

FIG. 5 is a schematic view illustrating a process furnace of the substrate processing apparatus and surrounding structures of the process furnace according to Embodiment 1.

FIG. 6 is a plan view illustrating a state where a susceptor on which a wafer is loaded is charged in a boat.

FIG. 7 is a sectional view illustrating a state where susceptors on which wafers are loaded are charged in the boat.

FIG. 8 is a sectional view illustrating a modification example of the boat in which susceptors loaded with wafers are charged.

FIG. 9 is a sectional view illustrating a modification example of the boat in which susceptors loaded with wafers are charged.

FIG. 10 is a sectional view illustrating a state where susceptors on which wafers are loaded are charged in the boat.

FIG. 11 is a sectional view illustrating a state where susceptors on which wafers are loaded are charged in the boat of the substrate processing apparatus of the embodiment 1.

FIG. 12 is a sectional view illustrating a state where susceptors on which wafers are loaded are charged in a boat of a substrate processing apparatus of Embodiment 2.

FIG. 13 is a sectional view illustrating a state where susceptors on which wafers are loaded are charged in a boat of a substrate processing apparatus of Embodiment 3.

FIG. 14 is a sectional view illustrating a state where susceptors on which wafers are loaded are charged in a boat of a substrate processing apparatus of Embodiment 4.

FIG. 15 is a sectional view illustrating a state where susceptors on which wafers are loaded are charged in a boat of a substrate processing apparatus of Embodiment 5.

FIG. 16 is a sectional view illustrating a state where susceptors on which wafers are loaded are charged in a boat of a substrate processing apparatus of Embodiment 6.

FIG. 17 is a sectional view illustrating a state where susceptors on which wafers are loaded are charged in a boat of a substrate processing apparatus of Embodiment 7.

### DETAILED DESCRIPTION OF THE PREFERRED EMBODIMENTS

In the following description of the present invention, if necessary, the present invention will be explained after dividing it into a plurality of sections or embodiments. However, the sections or embodiments are related to each other unless they are mentioned otherwise. For example, one section or embodiment may be a modification example, a detailed explanation, or a supplementary explanation of a part or the whole of another section or embodiment.

Furthermore, in the following descriptions of the embodiments, although the quantity of elements (such as number, values, amount, and range) is mentioned, the embodiment is not limited to the mentioned quantity but also covers greater or smaller quantities unless mentioned otherwise or it is fundamentally apparent that the embodiment is limited to the mentioned quantity.

Furthermore, in the following descriptions of the embodiments, although elements (steps, etc.) are mentioned, they may not be essential elements unless they are mentioned otherwise or it is fundamentally apparent that they are essential elements.

Furthermore, in the following descriptions of the embodiments, when features such as shapes or positional relationships of elements are mentioned, they include approximate or similar features unless mentioned otherwise or it is fundamentally apparent. This is the same for values and ranges.

Furthermore, in the drawings attached to describe the embodiments, like elements are basically denoted by like reference numerals, and thus descriptions of these elements will not be repeated. Furthermore, for the purpose of easy understanding of the drawings, hatching lines may be used even in a plan view.

### Embodiment 1

In the current embodiment of the present invention, a substrate processing apparatus is configured as an example of a semiconductor manufacturing apparatus that performs various processing processes including a method of manufacturing semiconductor devices (such as integrated circuits, ICs). In the following description, explanations will be given on the case where the technical ideas of the present invention are applied to a vertical type substrate processing apparatus configured to perform a film-forming process on a semiconductor substrate (semiconductor wafer) by an epitaxial growth method, a film-forming process on a semiconductor substrate by a chemical vapor deposition (CVD) method, or an oxidation or diffusion process on a semiconductor substrate. Particularly, in the current embodiment, an explanation will be given on a batch type substrate processing apparatus configured to process a plurality of substrates at a time.

First, a substrate processing apparatus relevant to the current embodiment 1 will be described with reference to the attached drawings.

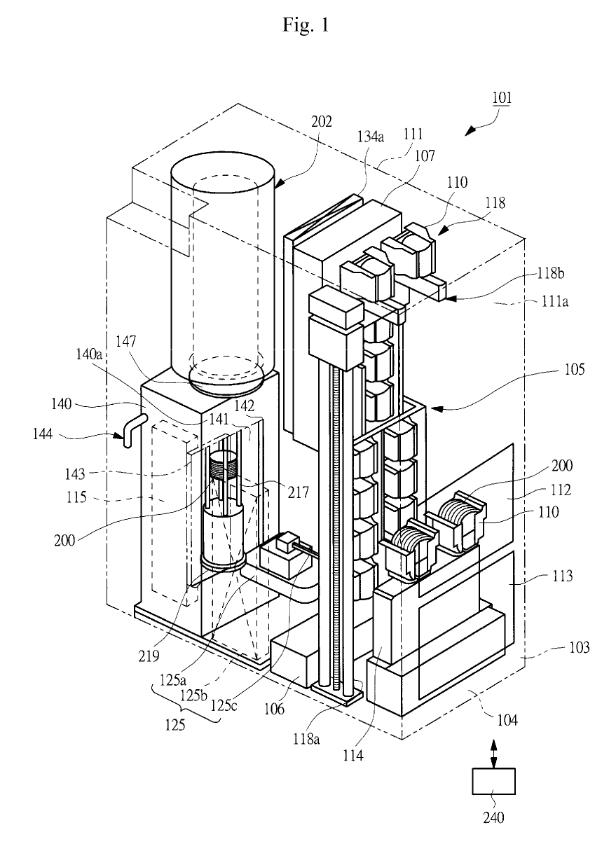

FIG. 1 is a schematic view illustrating a substrate processing apparatus 101 according to the current embodiment 1. As shown in FIG. 1, the substrate processing apparatus 101 of the current embodiment 1 is configured to use cassettes 110 as wafer carriers for accommodating a plurality of wafers (semiconductor substrates) 200 made of a material such as silicon. The substrate processing apparatus 101 includes a case 111. At the lower side of a front wall 111a of the case 111, an opening is formed as a front maintenance entrance 103 for maintenance works, and a front maintenance door 104 is installed on the front wall 111a of the case 111 to close and open the front maintenance entrance 103.

At the front maintenance door 104, a cassette carrying entrance (substrate container carrying entrance) 112 is formed so that the inside of the case 111 can communicate with the outside of the case 111 through the cassette carrying entrance 112, and the cassette carrying entrance 112 is configured to be opened and closed by using a front shutter (substrate container carrying entrance opening/closing mechanism) 113. At a side of the cassette carrying entrance 112 located inside the case 111, a cassette stage (substrate container stage) 114 is installed. A cassette 110 is carried on the cassette stage 114 or away from the cassette stage 114 by an in-process carrying device (not shown). On the cassette stage 114, a cassette 110 is placed by the in-process carrying device in a manner such that wafers 200 are vertically positioned in the cassette 110 and a wafer entrance of the cassette 110 is pointed upward.

Near the center portion of the case 111 in a front-to-back direction, a cassette shelf (substrate container shelf) 105 is installed. The cassette shelf 105 is configured to store a plurality of cassettes 110 in multiple rows and columns in a state where wafers 200 can be taken out of and into the cassettes 110. The cassette shelf 105 is installed in a manner such that the cassette shelf 105 can be transversely moved on a slide stage (horizontal movement mechanism) 106. In addition, at the upper side of the cassette shelf 105, a buffer shelf (substrate container storage shelf) 107 is installed, and cassettes 110 can also be stored on the buffer shelf 107.

Between the cassette stage 114 and the cassette shelf 105, a cassette carrying device (substrate container carrying device) 118 is installed. The cassette carrying device 118 includes a cassette elevator (substrate container elevating mechanism) 118a capable of moving upward and downward while holding a cassette 110, and a cassette carrying mechanism (substrate container carrying mechanism) 118b as a carrying mechanism. Cassettes 110 can be carried among the cassette stage 114, the cassette shelf 105, and the buffer shelf 107 by continuous motions of the cassette elevator 118a and the cassette carrying mechanism 118b.

At the rear side of the cassette shelf 105, a wafer transfer mechanism (substrate transfer mechanism) 125 is installed. The wafer transfer mechanism 125 includes a wafer transfer device (substrate transfer device) 125a capable of rotating or straightly moving a wafer 200 on a horizontal plane, and a wafer transfer device elevator (substrate transfer device elevating mechanism) 125b configured to move the wafer transfer device 125a upward and downward. As shown schematically in FIG. 1, the wafer transfer device elevator 125b is installed at a left end part of the case 111. By continuous motions of the wafer transfer device elevator 125b and the wafer transfer device 125a, tweezers (substrate holder) 125c of the wafer transfer device 125a can charge and discharge a wafer 200 on and from a susceptor functioning as a wafer stage or a susceptor placed at a susceptor holding mechanism (not shown).

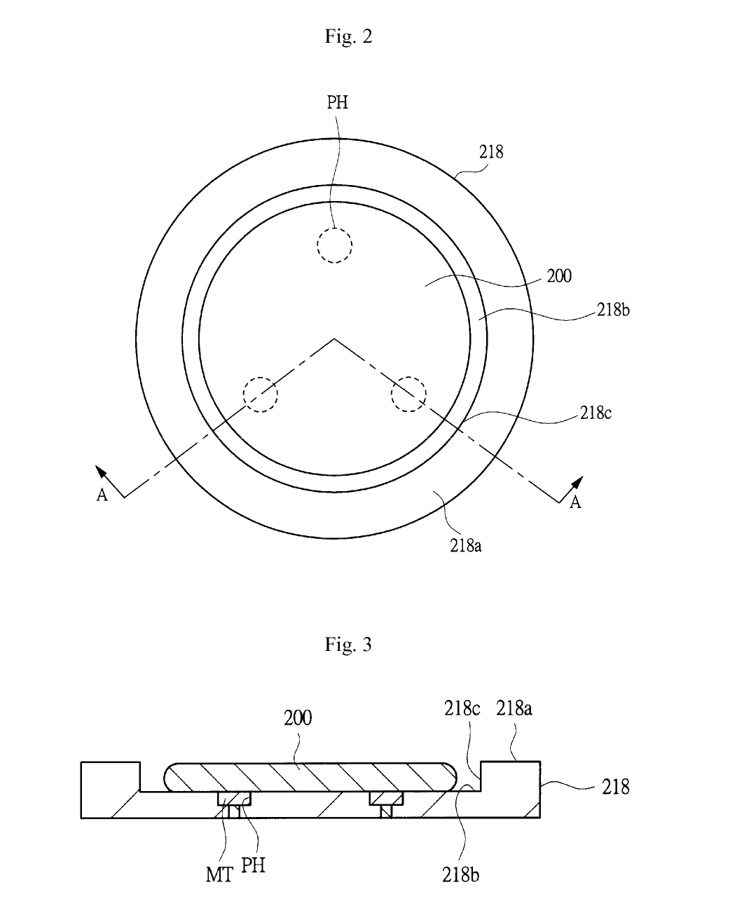

A state of charging a wafer 200 on a susceptor in the susceptor holding mechanism, and a state of discharging the wafer 200 from the susceptor in the susceptor holding mechanism are shown in below. FIG. 2 is a top view illustrating a state where a wafer 200 is charged on a susceptor 218, and FIG. 3 is a sectional view taken along line A-A of FIG. 2. First, as shown in FIG. 2, the susceptor 218 is shaped like a circular disk. The susceptor 218 includes a circular peripheral portion 218a and a circular center portion 218b that are concentrically provided. A wafer 200 having a circular disk shape is loaded on the center portion 218b of the susceptor 218. That is, the susceptor 218 has a circular disk shape greater than the wafer 200, and the wafer 200 is accommodated in the center portion 218b of the susceptor 218. In addition, as shown in FIG. 3, the height of the peripheral portion 218a of the susceptor 218 is greater than the height of the center portion 218b of the susceptor 218, and a stepped part 218c is formed on the susceptor 218 in a boundary region between the peripheral portion 218a and the center portion 218b. That is, the susceptor 218 has a shape in which the center portion 218b is concave from the peripheral portion 218a, and the wafer 200 is loaded on the concave center portion 218b. In other words, the thickness of the center portion 218b of the susceptor 218 is less than the thickness of the peripheral portion 218a of the susceptor 218. In addition, as shown in FIGS. 2 and 3, a plurality of pin holes PH are formed in the center portion 218b, and members MT are inserted in the pin holes PH. In this way, the wafer 200 is charged on the susceptor 218.

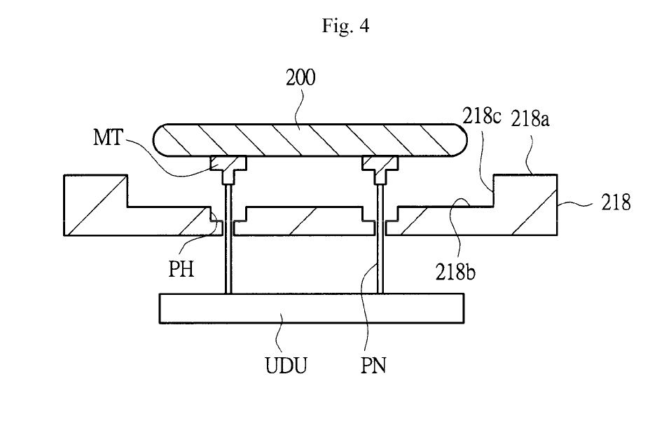

Next, an explanation will be given on an exemplary case where the wafer 200 is discharged from the susceptor 218 in the susceptor holding mechanism. FIG. 4 is a sectional view illustrating a state where the wafer 200 is separated from the susceptor 218. As shown in FIG. 4, in the susceptor holding mechanism, push-up pins PN configured to push up the wafer 200, and a push-up pin elevating mechanism UDU configured to raise and lower the push-up pins PN are installed. First, the susceptor holding mechanism adjusts the positions of the push-up pins PN so that the push-up pins PN can make contact with the members MT inserted in the pin holes PH formed in the susceptor 218, and the push-up pins PN are moved upward by the push-up pin elevating mechanism UDU. Then, as shown in FIG. 4, the members MT inserted in the pin holes PH, and the wafer 200 are separated from the susceptor 218. In this way, the wafer 200 can be discharged from the susceptor 218. It will be understood that the wafer 200 can be charged to and discharged from a position between the tweezers (substrate holder) 125c of the wafer transfer device 125a and the susceptor 218. In addition, so as to prevent damage of the wafer 200 and suppress heat radiation through the pin holes PH when the wafer 200 is pushed upward, it is preferable that tips of the pin holes push-up pins PN have a flange shape.

The substrate processing apparatus 101 of the current embodiment 1 includes a susceptor moving mechanism (not shown) as well as the susceptor holding mechanism. The susceptor moving mechanism is configured to charge and discharge the susceptor 218 to and from a position between the susceptor holding mechanism and a boat 217 (substrate holding tool).

Next, as shown in FIG. 1, at the rear side of the buffer shelf 107, a cleaning unit 134a including a supply fan and a dust filter is installed to supply clean air as purified atmosphere into the substrate processing apparatus 101. The cleaning unit 134a is configured to circulate clean air in the case 111. In addition, at a right end side opposite to the wafer transfer device elevator 125b, a cleaning unit (not shown) including a supply fan and a dust filter is installed to supply clean air. Clean air drawn through the cleaning unit (not shown) flows around the wafer transfer device 125a, and then the clean air is sucked by an exhaust device (not shown) and discharged to the outside of the case 111.

At the rear side of the wafer transfer device (substrate transfer device) 125a, a pressure-resistant case 140 is installed, which can be kept at a pressure lower than atmospheric pressure (hereinafter referred to as a negative pressure). The pressure-resistant case 140 forms a loadlock chamber 141 which is a loadlock type standby chamber having a volume sufficient to accommodate the boat 217.

At a front wall 140a of the pressure-resistant case 140, a wafer carrying entrance (substrate carrying entrance) 142 is formed. The wafer carrying entrance 142 is configured to be closed and opened by using a gate valve (substrate carrying entrance opening/closing mechanism) 143. A pair of sidewalls of the pressure-resistant case 140 are respectively connected to a gas supply pipe 144 used to supply an inert gas such as nitrogen gas into the loadlock chamber 141, and an exhaust pipe (not shown) used to exhaust the loadlock chamber 141 to a negative pressure.

At the upper side of the loadlock chamber 141, a process furnace (reaction furnace) 202 is installed. The bottom side of the process furnace 202 is configured to be opened and closed by a furnace port gate valve (furnace port opening/closing mechanism) 147.

As shown schematically in FIG. 1, a boat elevator (substrate holding tool elevating mechanism) 115 is installed at the loadlock chamber 141 to raise and lower the boat 217. At an arm (not shown) connected to the boat elevator 115 as a connection tool, a seal cap 219 is horizontal installed as a cover body. The seal cap 219 is configured to support the boat 217 vertically and close the bottom side of the process furnace 202.

The boat 217 includes a plurality of pillars (holding members) and is configured to hold a plurality of susceptors 218 (for example, about fifty to one hundred susceptors 218) horizontally in a state where the centers of the susceptors 218 are aligned and arranged in a vertical direction. Parts of the substrate processing apparatus 101 are electrically connected to a controller 240, and the controller 240 is configured to control operations of the parts of the substrate processing apparatus 101.

The substrate processing apparatus 101 of the current embodiment 1 is configured as schematically described above. Hereinafter, operations of the substrate processing apparatus 101 will be described. In the following description, the controller 240 controls each part of the substrate processing apparatus 101.

As shown in FIG. 1, before a cassette 110 is carried onto the cassette stage 114, the front shutter 113 is moved to open the cassette carrying entrance 112. Thereafter, the cassette 110 is carried through the cassette carrying entrance 112 and is placed on the cassette stage 114. At this time, the cassette 110 is placed in a manner such that wafers 200 are vertically positioned with reference to the cassette stage 114 and a wafer entrance of the cassette 110 is oriented upward.

Thereafter, the cassette 110 is picked up from the cassette stage 114 and rotated counterclockwise by 90° in a longitudinal direction toward the back side of the case 111 by the cassette carrying device 118 so that the wafers 200 inside the cassette 110 are horizontally positioned and the wafer entrance of the cassette 110 is oriented to the back side of the case 111. Next, the cassette 110 is automatically carried by the cassette carrying device 118 to a specified position of the cassette shelf 105 or the buffer shelf 107. That is, the cassette 110 is transferred to the cassette shelf 105 by the cassette carrying device 118 after being temporarily stored on the buffer shelf 107, or the cassette 110 is directly transferred to the cassette shelf 105 by the cassette carrying device 118.

Thereafter, the slide stage 106 moves the cassette shelf 105 horizontally so that a cassette 110 to be moved can be placed at a position corresponding to the wafer transfer device 125a. A wafer 200 is picked up from the cassette 110 through the wafer entrance of the cassette 110 by the tweezers 125c of the wafer transfer device 125a. At this time, in the susceptor holding mechanism, push-up pins are moved up by the push-up pin elevating mechanism UDU. Next, the wafer 200 is placed on the push-up pins PN by the wafer transfer device 125a. Then, the push-up pin elevating mechanism UDU lowers the push-up pins PN on which the wafer 200 is placed so as to hold the wafer 200 on a susceptor 218.

Next, the wafer carrying entrance 142 of the loadlock chamber 141 which is previously kept at atmospheric pressure is opened by operating the gate valve 143, and the susceptor 218 is discharged from the susceptor holding mechanism by the susceptor moving mechanism. Then, the susceptor moving mechanism carries the discharged susceptor 218 into the loadlock chamber 141 through the wafer carrying entrance 142 and charges the susceptor 218 into the boat 217.

The wafer transfer device 125a returns to the cassette 110 and charges the next wafer 200 to the susceptor holding mechanism. The susceptor moving mechanism returns to the susceptor holding mechanism and charges a susceptor on which the next wafer 200 is placed to the boat 217.

If a predetermined number of susceptors charged into the boat 217, the wafer carrying entrance 142 is closed by using the gate valve 143, and the loadlock chamber 141 is decompressed by vacuum evacuation through the exhaust pipe. When the loadlock chamber 141 is decompressed to the same pressure as the inside pressure of the process furnace 202, the bottom side of the process furnace 202 is opened by operating the furnace port gate valve 147. Next, the seal cap 219 is lifted by the boat elevator 115 so that the boat 217 supported on the seal cap 219 can be loaded into the process furnace 202.

After the boat 217 is loaded, a predetermined process is performed on the wafers 200 inside the process furnace 202. After the wafers 200 are processed, the boat 217 is unloaded by the boat elevator 115. In addition, the inside pressure of the loadlock chamber 141 is adjusted back to atmospheric pressure, and the gate valve 143 is opened. Thereafter, in an approximate reverse order to the above-described order, the processed wafers 200 and the cassettes 110 are carried to the outside of the case 111. In this way, the substrate processing apparatus 101 of the current embodiment 1 is operated.

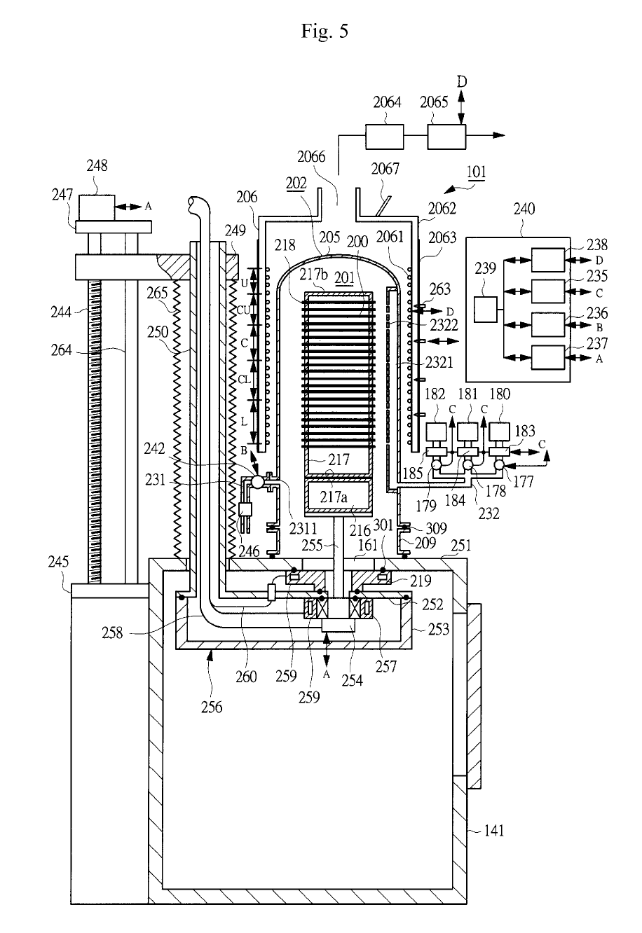

Next, the process furnace 202 of the substrate processing apparatus 101 of the current embodiment 1 will be described with reference to the attached drawings. FIG. 5 is a schematic view and a vertical cross-sectional view which illustrates the process furnace 202 of the substrate processing apparatus 101 and surrounding structures of the process furnace 202 according to the embodiment 1.

As shown in FIG. 5, the process furnace 202 includes an induction heating device 206 configured to generate heat when a high-frequency current is applied. The induction heating device 206 is shaped like a cylinder and includes a radio frequency (RF) coil 2061 as an induction heating part, a wall part 2062, and a cooling wall 2063. The RF coil 2061 is connected to a high-frequency power source (not shown), and a high-frequency current can flow in the RF coil 2061 by the high-frequency power source.

The wall part 2062 is made of a metal such as a stainless steal material. The wall part 2062 has a cylindrical shape, and the RF coil 2061 is installed at the inner wall side of the wall part 2062. The RF coil 2061 is supported by a coil support part (not shown). The coil support part is supported by the wall part 2062 at a position between the RF coil 2061 and the wall part 2062 with a predetermined radial gap from the RF coil 2061.

At the outer wall side of the wall part 2062, the cooling wall 2063 is installed concentrically with the wall part 2062. An opening 2066 is formed in a center portion of the topside of the wall part 2062. A duct is connected to the downstream side of the opening 2066. A radiator 2064 which is a cooling device, and a blower 2065 which is an exhaust device are connected to the downstream side of the duct.

A cooling medium flow passage is formed approximately in the whole area of the cooling wall 2063 to circulate a cooling medium such as cooling water. The cooling wall 2063 is connected to a cooling medium supply part configured to supply a cooling medium (not shown) and a cooling medium discharge part configured to discharge the cooling medium. By supplying a cooling medium into the cooling medium flow passage from the cooling medium supply part and discharging the cooling medium through the cooling medium discharge part, the cooling wall 2063 can be cooled, and thus the wall part 2062 and the inside of the wall part 2062 can be cooled by thermal conduction.

Inside the RF coil 2061, an outer tube 205 is installed concentrically with the induction heating device 206 as a reaction tube constituting a reaction vessel. The outer tube 205 is made of a heat-resistant material such as quartz (SiO₂) and has a cylindrical shape with a closed top side and an opened bottom side. Inside the outer tube 205, a process chamber 201 is formed. The process chamber 201 is configured to accommodate semiconductor substrates such as wafers 200 by using the boat 217 and induction target parts such as susceptors 218 in a manner such that the wafers 200 are horizontally positioned and vertically arranged in multiple stages.

At the lower side of the outer tube 205, a manifold 209 is disposed concentrically with the outer tube 205. The manifold 209 is made of a material such as quartz (SiO₂) or stainless steel and has a cylindrical shape with opened top and bottom sides. The manifold 209 is installed to support the outer tube 205. In addition, between the manifold 209 and the outer tube 205, an O-ring 309 is installed as a seal member. The manifold 209 is supported by a holder (not shown) so that the outer tube 205 can be vertically installed. In this way, the outer tube 205 and the manifold 209 constitute the reaction vessel. Here, the manifold 209 is not limited to the case where the manifold 209 is provided as a part separate from the outer tube 205. That is, the manifold 209 may not be provided as an individual apart but the manifold 209 and the outer tube 205 may be provided as one part.

At the inner sidewall of the outer tube 205, a gas supply chamber 2321 made of a quartz (SiO₂) material is disposed to supply gas to the respective wafers 200 disposed in the process chamber 201 in a lateral direction, and a gas exhaust outlet 2311 made of a quartz (SiO₂) material is disposed to exhaust the gas through a lateral side after the gas passes through the respective wafers 200 disposed in the process chamber 201.

The gas supply chamber 2321 is installed on the inner sidewall of the outer tube 205 by welding. The topside of the gas supply chamber 2321 is closed, and a plurality of gas supply holes 2322 are formed in the sidewall of the gas supply chamber 2321. Preferably, a plurality of gas supply chambers 2321 may be installed at a plurality of positions to uniformly supply gas to the plurality of wafers 200 placed in the boat 217. In addition, it is preferable that the gas supply directions of the gas supply holes 2322 of the plurality of gas supply chambers 2321 are parallel with each other. Furthermore, the gas supply chambers 2321 may be installed at positions which are symmetric with respect to the center line of the wafers 200. The gas supply holes 2322 may be formed at positions which correspond to gaps above the respective wafers 200 and are higher than the top surfaces of the wafers by predetermined heights, so as to uniformly supply gas to the respective wafers 200 placed in the boat 217.

At the outer wall of the outer tube 205, a gas exhaust pipe 231 is installed to communicate with the gas exhaust outlet 2311, and a gas supply pipe 232 is installed to communicate with the gas supply chamber 2321. Instead of installing the gas exhaust pipe 231 at a lower side of the outer wall of the outer tube, for example, the gas exhaust pipe 231 may be installed at the sidewall of the manifold 209. Furthermore, instead of installing a joint part between the gas supply chamber 2321 and the gas supply pipe 232 at a lower side of the outer wall of the lower plate 205, for example, the joint part may be installed at the sidewall of the manifold 209.

The upstream side of the gas supply pipe 232 is divided into three parts, and the three parts are respectively connected to a first gas supply source 180, a second gas supply source 181, and a third gas supply source 182 through valves 177, 178, and 179, and gas flow rate control devices such as mass flow controllers (MFCs) 183, 184, and 185. A gas flow rate control unit 235 is electrically connected to the MFCs 183, 184, and 185, and the valves 177, 178, and 179 so as to control the supply flow rate of gas to a desired level at a desired time.

A vacuum exhaust device 246 such as a vacuum pump is connected to the downstream sides of the gas exhaust pipe 231 through a pressure detector such as a pressure sensor (not shown) and a pressure regulator such as an automatic pressure controller (APC) valve 242. The pressure sensor and the APC valve 242 are electrically connected to the pressure control unit 236, and the pressure control unit 236 is configured to adjust the opening degrees of the APC valve 242 based on a pressure detected by the pressure sensor for controlling the inside pressure of the process chamber 201 to a desired level at a desired time.

At the lower side of the manifold 209, the seal cap 219 is installed as a furnace port cover to hermetically close the opened bottom side of the manifold 209. The seal cap 219 is made of a metal such as stainless steel and has a circular disk shape. On the top surface of the seal cap 219, an O-ring 301 is installed as a seal member configured to make contact with the bottom side of the manifold 209.

At the seal cap 219, a rotary mechanism 254 is installed. A rotation shaft 255 of the rotary mechanism 254 is connected to the boat 217 through the seal cap 219 so as to rotate the wafers 200 by rotating the boat 217.

The seal cap 219 is configured to be vertically lifted and lowered by an elevating motor 248 installed outside the process furnace 202 as an elevating mechanism, so as to load the boat 217 into the process chamber 201 and unload the boat 217 from the process chamber 201.

The rotary mechanism 254 and the elevating motor 248 are electrically connected to a driving control unit 237, and the driving control unit 237 controls the rotary mechanism 254 and the elevating motor 248 to perform desired operations at desired times.

In the induction heating device 206, the RF coil 2061 having a spiral shape is divided and installed in a plurality of upper and lower zones. For example, as shown in FIG. 5, from the lower side, an RF coil L, an RF coil CL, an RF coil C, an RF coil CU, and an RF coil U are installed in five zones, respectively. The RF coils of the five zones are configured to be individually controlled.

Near the induction heating device 206, temperature detectors such as radiation thermometers 263 are installed, for example, at four positions, to detect temperatures in the inside of the process chamber 201. At least one radiation thermometer 263 may be installed. However, if a plurality of radiation thermometers 263 are installed, temperature controllability may be improved.

The induction heating device 206 and the radiation thermometers 263 are electrically connected to a temperature control unit 238 so that power supply to the induction heating device 206 can be controlled based on temperature information detected by the radiation thermometers 263. Thus, by the temperature control unit 238, the inside temperature of the process chamber 201 can be controlled to obtain a desired temperature distribution at a desired time.

In addition, the temperature control unit 238 is also electrically connected to the blower 2065. The temperature control unit 238 is configured to control operations of the blower 2065 according to a preset operation recipe. By operating the blower 2065, an atmosphere of a gap between the wall part 2062 and the outer tube 205 can be discharged through the opening 2066. After being discharged through the opening 2066, the atmosphere is cooled while passing through the radiator 2064 and is discharged to equipment disposed at the downstream side of the blower 2065. That is, by operating the blower 2065 under the control of the temperature control unit 238, the induction heating device 206 and the outer tube 205 can be cooled.

The cooling medium supply part and the cooling medium discharge part connected to the cooling wall 2063 are configured to be controlled by the controller 240 at a predetermined time so that the flow rate of a cooling medium to the cooling wall 2063 can be adjusted for obtaining a desired cooling state. The case where the cooling wall 2063 is installed is preferable because heat dissipation to the outside of the process furnace 202 can be easily suppressed and the outer tube 205 can be cooled more easily. However, if a desired cooling state can be obtained by a cooling operation using the blower 2065, the cooling wall 2063 may not be installed.

In addition, at the topside of the wall part 2062, an explosion release outlet and an explosion release outlet opening/closing device 2067 are installed separate from the opening 2066. If there is an explosion as hydrogen and oxygen gases are mixed in the wall part 2062, a large pressure may be applied to the wall part 2062. In this case, relatively weak parts such as a bolt, a screw, and a panel of the wall part 2062 may be broken or blown to increase damages. To minimize such damages, the explosion release outlet opening/closing device 2067 is configured to open the explosion release outlet to release the inside pressure of the wall part 2062 when the inside pressure of the wall part 2062 becomes equal to or greater than a predetermined pressure because of an explosion.

Next, surrounding structures of the process furnace 202 of the current embodiment 1 will be described with reference to FIG. 5. At the outer surface of the loadlock chamber 141 which is a preliminary chamber, a lower base plate 245 is installed. A guide shaft 264 fitted in an elevating table 249, and a ball screw 244 screw-coupled to the elevating table 249 are installed on the lower base plate 245. An upper base plate 247 is installed on the upper ends of the guide shaft 264 and the ball screw 244 erected on the lower base plate 245. The ball screw 244 is rotated by the elevating motor 248 installed on the upper base plate 247. As the ball screw 244 is rotated, the elevating table 249 is lifted or lowered.

At the elevating table 249, a hollow elevating shaft 250 is installed in a direction perpendicular to the elevating table 249, and a joint part between the elevating table 249 and the elevating shaft 250 is hermetically sealed. The elevating shaft 250 is configured to be lifted and lowered together with the elevating table 249. The elevating shaft 250 penetrates a top plate 251 of the loadlock chamber 141. A penetration hole of the top plate 251 through which the elevating shaft 250 is inserted is sufficiently large so that the elevating shaft 250 does not make contact with the top plate 251 at the penetration hole. Between the loadlock chamber 141 and the elevating table 249, a bellows 265 is installed as a hollow flexible part configured to enclose the elevating shaft 250, so that the loadlock chamber 141 can be hermetically kept. The bellows 265 can be sufficiently expanded and contracted in accordance with lifting motions of the elevating table 249, and the bellows 265 has an inner diameter sufficiently greater than the outer diameter of the elevating shaft 250 so as not to make contact with the elevating shaft 250 during expansion or contraction.

An elevating base plate 252 is fixed to the lower end of the elevating shaft 250. A driving unit cover 253 is hermetically attached to the bottom surface of the elevating base plate 252 with a seal member such as an O-ring being disposed therebetween. The elevating base plate 252 and the driving unit cover 253 constitute a driving unit accommodation case 256. In this way, the inside of the driving unit accommodation case 256 is isolated from the inside atmosphere of the loadlock chamber 141.

In addition, the rotary mechanism 254 for the boat 217 is installed in the driving unit accommodation case 256, and the periphery of the rotary mechanism 254 is cooled by a cooling mechanism 257.

In addition, power cables 258 are connected from the upper end of the elevating shaft 250 to the rotary mechanism 254 through the hollow inside of the elevating shaft 250. In addition, cooling passages 259 are formed in the cooling mechanism 257 and the seal cap 219, and cooling water conduits 260 are connected to the cooling passages 259 to supply cooling water to the cooling passages 259. The cooling water conduits 260 extend through the hollow inside of the elevating shaft 250 from the upper end of the elevating shaft 250.

By rotating the ball screw 244 using the elevating motor 248, the driving unit accommodation case 256 can be lifted or lowered through the elevating table 249 and the elevating shaft 250.

If the driving unit accommodation case 256 is lifted, a furnace port 161 which is an opening of the process furnace 202 is closed by the seal cap 219 hermetically installed on the elevating base plate 252, and thus a wafer processible state can be made. If the driving unit accommodation case 256 is lowered, the boat 217 is also lowered together with the seal cap 219, and in this state, wafers 200 can be carried to an outside area.

The gas flow rate control unit 235, the pressure control unit 236, the driving control unit 237, and the temperature control unit 238 constitute a manipulation unit and an input/output unit and are electrically connected to a main control unit 239 that controls the overall operation of the substrate processing apparatus 101. The gas flow rate control unit 235, the pressure control unit 236, the driving control unit 237, the temperature control unit 238, and the main control unit 239 are configured as the controller 240. As described above, the process furnace 202 of the substrate processing apparatus 101, and surrounding structures of the process furnace 202 are configured according to the embodiment 1.

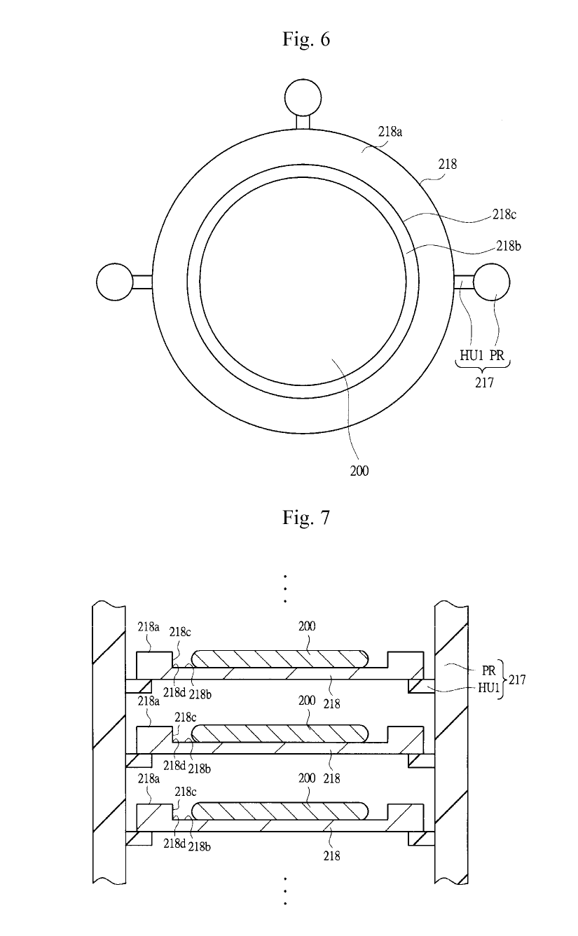

Next, an explanation will be given on an operation of charging a susceptor 218 on which a wafer is loaded into the boat 217. FIG. 6 is a plan view illustrating a state where a susceptor 218 on which a wafer 200 is loaded is charged in the boat 217. The boat 217 functions as a holder configured to hold a susceptor 218. The boat 217 includes a lower plate 217a (refer to FIG. 5) having a circular disk shape, a top plate 217b (refer to FIG. 5) having a circular disk shape, and three or four pillars made of quartz and connected between the lower plate 217a and the top plate 217b. As shown in FIG. 6, at each of the plurality of pillars PR, a holding part HU1 is formed to hold a susceptor 218 which is a support part on which a wafer 200 is loaded. The holding part HU1 protrudes from the pillar PR toward the center axis of the boat 217.

As shown in FIG. 6, a susceptor 218 configured to be loaded in the boat 217 has a circular disk shape having a diameter greater than that of a wafer 200, and a concave part is formed in a main surface of the disk-shaped susceptor 218. That is, a peripheral portion 218a and a center portion 218b which have different heights are formed on the susceptor 218. The thickness of the center portion 218b is less than that of the peripheral portion 218a. Therefore, a stepped part 218c is formed between the peripheral portion 218a and the center portion 218b. The center portion 218b formed inside the stepped part 218c has a diameter slightly greater than that of a wafer 200, and a wafer 200 is loaded on the center portion 218b in a manner such that the wafer 200 is accommodated in the center portion 218b. The susceptor 218 having this structure is made of a conductive material (carbon or carbon graphite). Preferably, the susceptor 218 may be made by coating the surface of a conductive material with a coating material such as silicon carbide (SiC). In this case, generation of contaminants from the conductive material can be suppressed.

It is preferable that the susceptor 218 has a circular disk shape because the wafer 200 can be uniformly heated in a circumferential direction. However, the susceptor 218 may have a plate shape having an elliptic main surface or a plate shape having a polygonal main surface.

Next, an explanation will be given with reference to side views illustrating a state where susceptors 218 on which wafers 200 are held are charged in the boat 217. FIG. 7 is a sectional view illustrating a state where susceptors 218 on which wafers 200 are held are charged in the boat 217. As shown in FIG. 7, the boat 217 includes the plurality of pillars PR extending in the extending direction of the boat 217 (the vertical direction in FIG. 7), and the holding parts HU1 installed on each of the pillars PR at regular intervals in the extending direction. The holding parts HU1 are installed at the same heights of the pillars PR, and end parts of a susceptor 218 is held by, for example, three holding parts HU1 installed at the same height. Therefore, the susceptor 218 held by the three holding parts HU1 can be horizontally disposed. In detail, as shown in FIG. 7, susceptors 218 are respectively loaded on the holding parts HU1 arranged at predetermined intervals in the extending direction of the boat 217. That is, in the boat 217, a plurality of susceptors 218 are stacked at predetermined intervals in the extending direction of the boat 217. In this way, the susceptors 218 are provided independent of the pillars PR in a manner such that the susceptors 218 can be charged in the boat 217 and discharged from the boat 217.

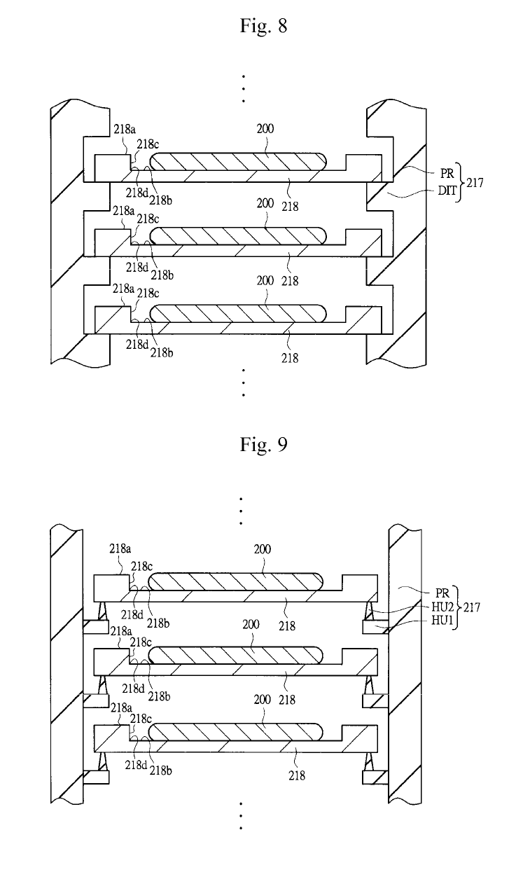

The holding parts HU1 configured to hold susceptors 218 are not limited to the shape protruding from the pillars PR. For example, as shown in FIG. 8, grooves DIT may be formed in the pillars PR to hold susceptors 218. That is, a plurality of grooves DIT are formed in a manner such that the grooves DIT are arranged at regular intervals in the extending direction of the pillars PR. The grooves DIT are formed at the same heights of the plurality of pillars PR, and end parts of a susceptor 218 is held by, for example, three grooves DIT formed at the same height. In this case, the susceptor 218 held by the three grooves DIT can be horizontally disposed. In detail, as shown in FIG. 8, susceptors 218 are respectively loaded on the grooves DIT arranged at predetermined intervals in the extending direction of the boat 217. That is, even in the case where the grooves DIT are formed in the pillars PR, the boat 217 can be configured to stack a plurality of susceptors 218 at predetermined intervals in the extending direction of the boat 217.

In addition, as shown in FIG. 9, so as to suppress heat transfer from susceptors 218 to the boat 217 by reducing contact areas between the susceptors 218 and the boat 217 while maintaining strength, polygonal or cylindrical pillar shaped holding parts HU2 having a trapezoidal sectional shape of which the topside is short than the bottom side may be installed on the holding parts HU1. By this, direct heat conduction from the susceptors 218 to the holding parts HU2 can be suppressed, and deformation and breakage of the holding parts HU2 and the holding parts HU1 can be prevented.

That is, the plurality of holding parts HU1 are formed at regular intervals in the extending direction of the pillars PR, and the plurality of holding parts HU2 are formed on the plurality of holding parts HU1, respectively. The holding parts HU2 are formed at the same heights of the plurality of pillars PR, and end parts of a susceptor 218 is held by, for example, three holding parts HU2 formed at the same height. In this case, the susceptor 218 held by the three holding parts HU2 can be horizontally disposed. In detail, as shown in FIG. 9, in the boat 217, susceptors 218 are respectively loaded on the holding parts HU2 arranged at predetermined intervals in the extending direction of the boat 217. That is, even in the case where the holding parts HU1 and the holding parts HU2 are formed on the pillars PR, the boat 217 can be configured to stack a plurality of susceptors 218 at predetermined intervals in the extending direction of the boat 217.

In addition, as shown in FIG. 5, for example, an insulating tube 216 having a cylindrical shape and made of a heat-resistant material such as quartz (SiO₂) is disposed at the lower part of the boat 217, so that heat generated from the induction heating device 206 by induction heating may not be easily transferred to the manifold 209. Instead of providing the insulating tube 216 as a part separated from the boat 217, the insulating tube 216 and the boat 217 may be provided as one part. In addition, instead of the insulating tube 216, a plurality of insulating plates may be installed at the lower part of the boat 217.

To prevent impurities from entering into films when a film-forming process is performed on wafers 200 in the process chamber 201 as shown in FIG. 5, it is preferable that the boat 217 is made of a highly-pure material that does not release contaminants. In addition, if the boat 217 is made of a material having a high thermal conductivity, the quartz insulating tube 216 disposed at the lower part of the boat 217 is thermally degraded. Thus, it is preferable that the boat 217 is made of a material having a lower thermal conductivity. In addition, since it is preferable to suppress thermal influence from the boat 217 to wafers 200 held on the susceptors 218, the boat 217 may be made of a material that is not induction-heated by the induction heating device 206. Since quartz satisfies the above-mentioned requirements, the boat 217 is made of quartz.

Next, with reference to FIG. 5, an explanation will be given a process of forming films on wafers 200 by using the substrate processing apparatus 101 of the current embodiment 1. In the following description, the controller 240 controls each part of the substrate processing apparatus 101. First, as shown in FIG. 5, the boat 217 is loaded in the process furnace 202. In this state, a high-frequency current is applied to the induction heating device 206. Then, a high-frequency electromagnetic field is generated in the process furnace 202, and the high-frequency electromagnetic field causes eddy currents in the susceptors 218 which are induction target parts. In the susceptors 218, the eddy currents cause induction heating, and thus the susceptors 218 are heated. In detail, since the eddy currents flow in the peripheral portions of the susceptors 218 which are induction target parts, the peripheral portions of the susceptors 218 are mainly induction-heated by the induction heating device 206. Then, in the susceptors 218 whose peripheral portions are heated, heat flows from the peripheral portions to the center portions of the susceptors 218 by thermal conduction. Thus, the entire parts (peripheral portions and center portions) of the susceptors 218 are heated. When the susceptors 218 are heated in this way, heat is transferred to wafers 200 held on the susceptors 218 by thermal conduction so that the wafers 200 can be heated.

In this way, the substrate processing apparatus 101 of the current embodiment 1 uses an induction heating method to heat the wafers 200. At this time, although the wafers 200 are directly induction-heated by the high-frequency electromagnetic field generated by applying a high-frequency current to the induction heating device 206, the heating degree is not sufficient in many cases. Therefore, in the induction heating method of this embodiment, the susceptors 218 are used as induction target parts for efficient induction heating. That is, in the induction heating type substrate processing apparatus 101, the susceptors 218 are used for efficient induction heating. The susceptors 218 are efficiently induction-heated in this way, and then the wafers 200 held on the susceptors 218 are heated by thermal conduction from the susceptors 218. That is, the susceptors 218 are used to hold wafers 200 thereon, and in addition to this function, the susceptors 218 are induction-heated by a high-frequency electromagnetic field.

After heating the wafers 200 in this way, a source gas is introduced into the process furnace 202. In detail, as shown in FIG. 5, a first process gas is supplied from the first gas supply source 180, and the flow rate of the first process gas is controlled by the MFC 183. Then, the first process gas flows through the gas supply pipe 232 after passing through the valve 177 and is introduced into the gas supply chamber 2321 where the first process gas is intruded into the process chamber 201 through the gas supply holes 2322. A second process gas is supplied from the second gas supply source 181, and the flow rate of the second process gas is controlled by the MFC 184. Then, the second process gas flows through the gas supply pipe 232 after passing through the valve 178 and is introduced into the gas supply chamber 2321 where the second process gas is intruded into the process chamber 201 through the gas supply holes 2322. A third process gas is supplied from the third gas supply source 182, and the flow rate of the third process gas is controlled by the MFC 185. Then, the third process gas flows through the gas supply pipe 232 after passing through the valve 179 and is introduced into the gas supply chamber 2321 where the first process gas is intruded into the process chamber 201 through the gas supply holes 2322.

The first process gas, the second process gas, and the third process gas introduced into the process chamber 201 in this way are supplied to the surfaces of the wafers 200 held on the susceptors 218 charged in the boat 217, so that the gases can undergo reaction with the heated surfaces of the wafers 200 to form films on the wafers 200. Thereafter, the gases flows from the process chamber 201 to the gas exhaust pipe 231 through the gas exhaust outlet 2311 and are exhausted by the vacuum exhaust device 246.

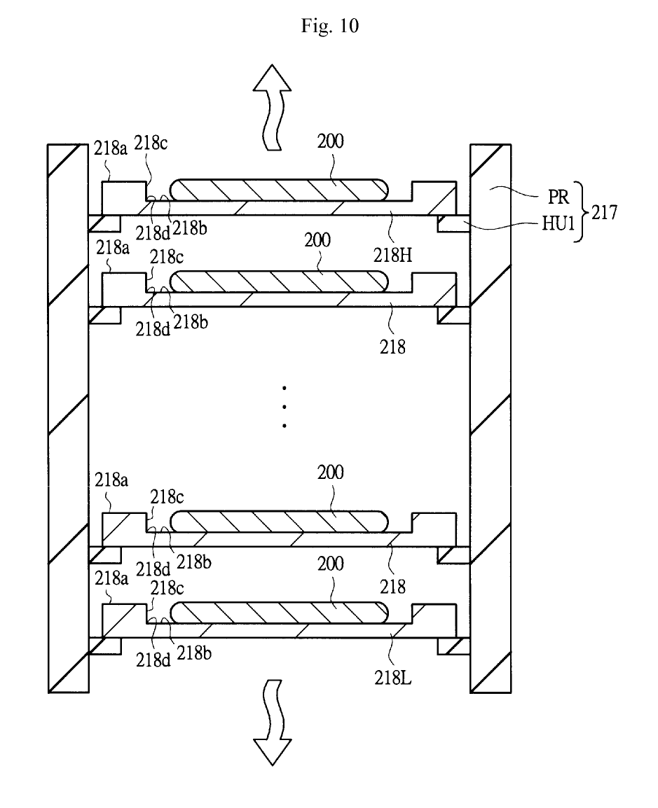

FIG. 10 is a sectional view illustrating a state where susceptors 218 on which wafers 200 are held are charged in the boat 217. As shown in FIG. 10, in the boat 217 loaded in the process chamber 201, susceptors 218 on which wafers 200 are held are stacked and arranged in the extending direction of the pillars PR. In this way, in the substrate processing apparatus 101 of the current embodiment 1, films can be formed on a plurality of wafers 200 at a time.

Here, as shown in FIG. 10, at the susceptors 218 which are induction target parts, the stepped parts 218c are formed between the peripheral portions 218a and the center portions 218b, and the wafers 200 are loaded on the concave center portions 218b. Merits of this structure will now be explained.

For example, an explanation will be on the case where a stepped part is not provided between the peripheral portion and the center portion of a susceptor and a wafer is held on the susceptor which is flat from the peripheral portion to the center portion. In this case, since the wafer having a thickness is held on a flat main surface of the susceptor, a stepped part is formed between the surface of the susceptor and the surface of the wafer by the thickness of the wafer. Thus, gas flowing from the side of the susceptor may collide with the stepped part formed between the surface of the susceptor and the surface of the wafer, and thus turbulent flows and stagnation may occur easily. Then, since the gas is not uniformly supplied to the surface of the wafer, it may be difficult to form a film uniformly on the entire surface of the wafer.

In addition, if the wafer is processed at a high temperature, the wafer held on the susceptor may be easily out of alignment due to reasons such as thermal deformation of the wafer and rotation of the boat 217. That is, since the wafer held on the flat susceptor is not fixed, the wafer may be easily misaligned. In case of misalignment, since wafers loaded on a plurality of susceptors are misaligned more or less, for example, the thicknesses of films formed on the wafers may not be uniform among the wafers.

In addition, if a wafer is held on the susceptor which is flat from the peripheral portion to the center portion, gas may be easily supplied even to an end part of the rear side of the wafer, and thus a film may be easily formed even around the rear side of the wafer.

However, referring to FIG. 10, in the susceptors 218, the stepped parts 218c are formed between the peripheral portions 218a and the center portions 218b, and wafers 200 are loaded on the concave center portions 218b. In this case, the above-mentioned demerits can be prevented.

Preferably, the stepped parts 218c are formed between the peripheral portions 218a and the center portions 218b of the susceptors 218 in a manner such that when wafers 200 are placed, the top surfaces of the peripheral portions 218a and the wafers 200 are horizontally flat. Then, gas supplied from the sides of the susceptors 218 may flow on the peripheral portions 218a and smoothly arrive at the surfaces of the wafers 200 without causing turbulent flows and stagnation. As a result, since gas can be uniformly supplied to the surfaces of the wafers 200, films may be formed uniformly on the entire surfaces of the wafers 200.

In addition, if the wafers 200 are processed at a high temperature, the wafers 200 may be easily out of alignment due to reasons such as thermal deformation. However, since the wafers 200 are loaded by the stepped parts 218c, misalignment of the wafers 200 can be surely suppressed. Therefore, it is possible to prevent misalignment of the wafers 200 loaded on the plurality of susceptors 218, and thus, for example, the thickness of films formed on the wafers 200 may not be varied among the wafers 200.

In addition, if the rear surfaces of the wafers 200 make contact with the surfaces of the center portions 218b of the susceptors 218 which are lower than the surfaces of the peripheral portions 218a of the susceptors 218 in a condition that the top surfaces of the peripheral portions 218a are horizontally flush with the top surfaces of the wafers 200, gas may be difficult to flow to the rear surfaces of the wafers 200. Therefore, deposition of films on the rear surfaces of the wafers 200 can be suppressed.

For the above-described reasons, in the susceptors 218 which are induction target parts, the stepped parts 218c are formed between the peripheral portions 218a and the center portions 218b, and the wafers 200 are loaded on the concave center portions 218b. However, in the case where the stepped parts 218c are formed between the peripheral portions 218a and the center portions 218b of the susceptors 218, the inventors have found that the current substrate processing apparatus 101 has the following problems.

Hereinafter, the problems found by the inventors will be explained. As shown in FIG. 5, the substrate processing apparatus 101 includes: the process furnace 202 configured to process substrates such as wafers therein; the susceptors 218 which are induction target parts each having a center portion thinner than a peripheral portion to accommodate wafers in the center portions and heat the wafers; and the boat 217 which is an induction target part holder configured to hold the susceptors 218 at predetermined intervals in the extending direction of the process furnace 202. That is, as shown in FIG. 10, a plurality of susceptors 218 are disposed in the boat 217, and wafers 200 are loaded on the susceptors 218, respectively. In this case, although the peripheral portions 218a of the susceptors 218 can be kept at a constant temperature owing to eddy currents, the center portions 218b of the susceptors 218 are difficult to be heated by eddy currents because eddy currents are not easily generated in the center portions 218b. The temperature of the center portions 218b of the susceptors 218 is determined mainly by the balance among heat conduction from the peripheral portions 218a of the susceptors 218 heated by eddy currents, heat radiation from the upper and lower susceptors 218, and heat release at the center portions 218b of the susceptors 218. If there are upper and lower susceptors 218, heat release at the center portions 218b of the susceptors 218 is suppressed, and thus the temperature difference between the peripheral portions 218a and the center portions 218b of the susceptors 218 is not so great.

However, as shown in FIG. 10, in the case of susceptors 218H or 218L disposed on the uppermost or lowermost stage above or under which no susceptor 218 exists, the amount of heat released from the center portion 218b of the susceptor 218H or 218L is greater than the amount of heat conducted from the peripheral portion 218a of the susceptor 218H or 218L. In addition, since there is no upper or lower susceptor 218, the amount of heat radiation from a neighboring susceptor 218 is also low. Therefore, in the case of the susceptors 218H and 218L disposed on the uppermost and lowermost stages, the temperature of the center portion 218b is significantly lower than the temperature of the peripheral portion 218a. In addition, since wafers 200 are loaded on the center portions 218b of the susceptors 218H and 218L, the center portions 218b are thinner than the peripheral portions 218a of the susceptors 218H and 218L. As a result, in the case of the susceptors 218H and 218L disposed on the uppermost and lowermost stages, stress may easily be concentrated on the stepped part 218c formed between the peripheral portion 218a and the center portion 218b, particularly, on a corner part 218d located at a side of the center portion 218b due to a temperature difference between the peripheral portion 218a and the center portion 218b. Stress can be easily concentrated on the corner part 218d even in terms of structure. If stress is concentrated in this way, problems may occur such as breakage of the susceptor 218H or 218L disposed on the uppermost or lowermost stage.

Furthermore, if the surface of the susceptors 218 are coated with a coating material, stress is concentrated on the stepped part 218c between the peripheral portion 218a and the center portion 218b of the susceptor 218H or 218L disposed on the uppermost or lowermost stage because of other reasons as well as the above-described temperature difference between the peripheral portion 218a and the center portion 218b. For example, the susceptor 218 (218H, 218L) may be made by forming a silicon carbide film on the surface of a carbon base material to a thickness of 120 μm. In this case, it is difficult to coat the stepped part 218c located between the peripheral portion 218a and the center portion 218b with silicon carbide in a good step coverage state. Thus, when the susceptor 218 (218H, 218L) is heated, stress is easily concentrated on the stepped part 218c, particularly, the corner part 218d of the center portion 218b because of a thickness variation of the silicon carbide film on the stepped part 218c and a linear expansion coefficient different between carbon and silicon carbide (carbon: 5×10⁻⁶/K, SiC: 6.6×10⁻⁶/K).

As described above, the susceptor 218H or 218L disposed on the uppermost or lowermost stage can be easily broken, and if it is coated, contaminants can be easily generated due to detachment of the coating material from a position around the stepped part 218c caused by stress concentration. If contaminants are generated, since the contaminants adhere to the surface of wafers 200, the yield of the wafer processing process may be decreased. That is, due to stress concentration on the stepped part 218c in the susceptor 218H or 218L disposed on the uppermost or lowermost stage, the susceptor 218H or 218L itself can be broken, and there is considerable potential of contamination. Therefore, the quality of films formed on the wafers 200 may be lowered.

However, according to the current embodiment 1 provided based on studies, the probability of breakage of the susceptor 218H or 218L and the potential of contamination, which are caused by stress concentration on the stepped part 218c of the susceptor 218H or 218L disposed on the uppermost or lowermost stage, can be suppressed or reduced to improve the film-forming quality of wafers 200. Hereinafter, an explanation will be given on the substrate processing apparatus 101 of the current embodiment 1 provided based on the studies.

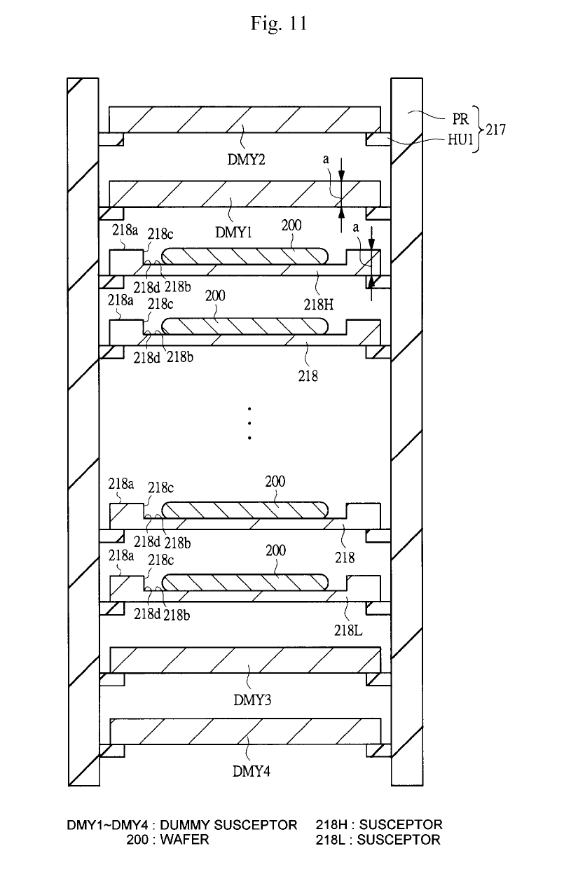

FIG. 11 is a sectional view illustrating a state where susceptors 218 on which wafers 200 are held are charged in the boat 217 of the substrate processing apparatus 101 of the current embodiment 1. As shown in FIG. 11, the boat 217 includes: the plurality of pillars PR extending in the extending direction of the boat 217 (the vertical direction in FIG. 11); and the holding parts HU1 installed on each of the pillars PR at regular intervals in the extending direction. The holding parts HU1 are installed at the same heights of the pillars PR, and end parts of a susceptor 218 is held by two holding parts HU1 installed at the same height. Therefore, the susceptor 218 held by the two holding parts HU1 can be horizontally disposed. In detail, as shown in FIG. 11, susceptors 218 are respectively loaded on the holding parts HU1 arranged at predetermined intervals in the extending direction of the boat 217. That is, in the boat 217, a plurality of susceptors 218 are stacked at predetermined intervals in the extending direction of the boat 217. In this way, the susceptors 218 are provided independent of the pillars PR in a manner such that the susceptors 218 can be charged in the boat 217 and discharged from the boat 217.

Referring to FIG. 11, among the susceptors 218 on which the wafers 200 are loaded, one disposed on the uppermost stage is referred as a susceptor 218H, and one disposed on the lowermost stage is referred as a susceptor 218L. Here, the current embodiment 1 is characterized by dummy susceptors DMY1 and DMY2 which are second induction target parts disposed above the uppermost susceptor 218H, and dummy susceptors DMY3 and DMY4 which are second induction target parts disposed under the lowermost susceptor 218L.

That is, the dummy susceptor DMY1 is disposed at a position higher than the uppermost susceptor 218H by one stage, and the dummy susceptor DMY2 is disposed at a position higher than the dummy susceptor DMY1 by one stage. Similarly, the dummy susceptor DMY3 is disposed at a position lower than lowermost susceptor 218L by one stage, and the dummy susceptor DMY4 is disposed at a position lower than the dummy susceptor DMY3 by one stage.

A wafer 200 is not loaded on any of the dummy susceptors DMY1 to DMY4, and the surfaces of the dummy susceptors DMY1 to DMY4 are flat. That is, in the current embodiment 1, the dummy susceptors DMY1 to DMY4 are not used to load wafers 200 thereon and have flat surfaces. Furthermore, in the current embodiment 1, the dummy susceptors DMY1 to DMY4 have the same diameter and thickness (a) as those of the other ordinary susceptors 218 used to load wafers 200 thereon.

In the current embodiment 1, as shown in FIG. 11, the dummy susceptors DMY1 and DMY2 are provided above the uppermost susceptor 218H. Therefore, the temperature difference between the peripheral portion 218a and the center portion 218b of the uppermost susceptor 218H can be reduced.

For example, it will now be considered that the dummy susceptors DMY1 and DMY2 are not provided above the uppermost susceptor 218H. In this case, since a susceptor 218 that can block heat radiation is not disposed above the uppermost susceptor 218H, the uppermost susceptor 218H radiates more heat than a susceptor 218 disposed between upper and lower neighboring susceptors 218. In addition, since there is no susceptor 218 that is being heated above the uppermost susceptor 218H, heat is not radiated from an upper susceptor 218 to the uppermost susceptor 218H. Particularly, although the peripheral portion 218a of the uppermost susceptor 218H is heated by induced eddy currents, the center portion 218b of the uppermost susceptor 218H is not easily induction-heated because eddy currents are not easily generated in the center portion 218b. Therefore, in the uppermost susceptor 218H, the temperature difference between the peripheral portion 218a and the center portion 218b is significantly large.

On the other hand in the current embodiment 1, the dummy susceptors DMY1 and DMY2 are disposed above the uppermost susceptor 218H. Thus, since heat radiated from the uppermost susceptor 218H is blocked by the dummy susceptors DMY1 and DMY2, heat radiation from the uppermost susceptor 218H can be reduced. Preferably, the dummy susceptors DMY1 and DMY2 may be made of the same material as that used to make the other ordinary susceptors 218. Owing to this, the same thermal characteristics as those of the ordinary other ordinary susceptors 218 can be attained, and temperature adjustment can be easily carried out. Since the dummy susceptors DMY1 and DMY2 are induction target parts, the dummy susceptors DMY1 and DMY2 are also heated by the induction heating device 206. Therefore, heat is radiated to the center portion 218b of the uppermost susceptor 218H from the dummy susceptors DMY1 and DMY2 as the dummy susceptors DMY1 and DMY2 are induction-heated. As described above, according to the current embodiment 1, heat radiation from the center portion 218b of the uppermost susceptor 218H is suppressed, but radiation heat is provided to the center portion 218b of the uppermost susceptor 218H from the dummy susceptors DMY1 and DMY2. Therefore, the temperature difference between the peripheral portion 218a and the center portion 218b of the uppermost susceptor 218H can be reduced.

This reduces stress caused by the temperature difference between the peripheral portion 218a and the center portion 218b of the uppermost susceptor 218H, and thus less stress is imposed on the stepped part 218c between the peripheral portion 218a and the center portion 218b of the uppermost susceptor 218H. Therefore, the uppermost susceptor 218H is not easily broken, and if the uppermost susceptor 218H is coated, the coating material is not easily detached so that generation of contaminants can be suppressed. That is, in the current embodiment 1, breakage of the uppermost susceptor 218H can be prevented, and the potential of contamination can be reduced. Therefore, notable effect, that is, improvement of film-forming quality of wafers 200 can be attained.

Similarly, in the current embodiment 1, as shown in FIG. 11, the dummy susceptors DMY3 and DMY4 are provided under the lowermost susceptor 218L. Therefore, the temperature difference between the peripheral portion 218a and the center portion 218b of the lowermost susceptor 218L can be reduced.

That is, according to the current embodiment 1, the dummy susceptors DMY3 and DMY4 are disposed under the lowermost susceptor 218L. Thus, since heat radiated from the lowermost susceptor 218L is blocked by the dummy susceptors DMY3 and DMY4, heat radiation from the lowermost susceptor 218L can be reduced. Preferably, the dummy susceptors DMY3 and DMY4 may be made of the same material as that used to make the other ordinary susceptors 218. Owing to this, the same thermal characteristics as those of the ordinary other ordinary susceptors 218 can be attained, and temperature adjustment can be easily carried out. Since the dummy susceptors DMY3 and DMY4 are induction target parts, the dummy susceptors DMY3 and DMY4 are also heated by the induction heating device 206. Therefore, heat is radiated to the center portion 218b of the lowermost susceptor 218L from the dummy susceptors DMY3 and DMY4 as the dummy susceptors DMY3 and DMY4 are induction-heated.

As described above, according to the current embodiment 1, at least one of the following effects can be attained.

(1) In the lowermost susceptor 218L, heat radiation from the center portion 218b is suppressed, and radiation heat is provided to the center portion 218b from the dummy susceptors DMY3 and DMY4. Therefore, in the lowermost susceptor 218L, the temperature difference between the peripheral portion 218a and the center portion 218b can be reduced.

This reduces stress caused by the temperature difference between the peripheral portion 218a and the center portion 218b of lowermost susceptor 218L, and thus less stress is imposed on the stepped part 218c between the peripheral portion 218a and the center portion 218b of the lowermost susceptor 218L. Therefore, the lowermost susceptor 218L is not easily broken, and if the lowermost susceptor 218L is coated, the coating material is not easily detached so that generation of contaminants can be suppressed. That is, in the current embodiment 1, breakage of the lowermost susceptor 218L can be prevented, and the potential of contamination can be reduced. Therefore, the film-forming quality of wafers 200 can be improved.

(2) Generally, the amount of heat radiation from the uppermost susceptor 218H or the lowermost susceptor 218L is greater than the amount of heat radiation from a susceptor 218 disposed in the center portion of the boat 217. However, according to the current embodiment 1, supplemental heat can be provided to the uppermost susceptor 218H or the lowermost susceptor 218L by induction heating of the dummy susceptors DMY1 to DMY4. Therefore, the temperature of susceptors 218 can be uniformly maintained regardless of whether the position of the susceptor 218 is the center portion, the uppermost stage, or the lowermost stage of the boat 217. This means that the temperature deviation of wafers 200 that are processed at a time can be reduced. As a result, the thickness and quality of films formed on a plurality of wafers 200 can be maintained more uniformly.

(3) In the current embodiment 1, since the dummy susceptors DMY1 to DMY4 have the same thickness as that of the ordinary susceptors 218, the dummy susceptors DMY1 to DMY4 can be charged in the boat 217 by using the holding parts HU1 installed at regular intervals on the pillars PR of the boat 217 without any change. Therefore, even when the process number of ordinary susceptors 218 on which wafers 200 are held is changed, since the dummy susceptors DMY3 and DMY4 can be supported on the regularly-installed holding parts HU1, the boat 217 can be used without replacing the boat 217. That is, in the current embodiment 1, the dummy susceptors DMY1 to DMY4 are configured as structural members having high general-purpose properties.

(4) When the ordinary susceptors 218 on which wafers 200 are held are charged into and discharged from the boat 217 together with the dummy susceptors DMY1 to DMY4 by picking up them from the bottom sides thereof, the distance between the dummy susceptors DMY1 to DMY4, the distance between the dummy susceptors DMY1 to DMY4 and the ordinary susceptors 218, and the distance between the ordinary susceptors 218 are equally maintained. That is, the dummy susceptors DMY1 to DMY4 can be charged in and discharged from the boat 217 in the same way as the ordinary susceptors 218.

(5) Since susceptors are not provided above and under the dummy susceptors DMY1 to DMY4, particularly, during induction heating, the amount of heat radiation or heating may be insufficient at the center portions 218b of the dummy susceptors DMY1 to DMY4 where eddy currents are not easily generated. Thus, the temperature of the center portion 218b of the dummy susceptors DMY1 to DMY4 may be low. However, in the current embodiment 1, the dummy susceptors DMY1 to DMY4 do not have stepped parts 218c and are flat. That is, in the dummy susceptors DMY1 to DMY4 of the current embodiment 1, countersinks are not formed between the peripheral portions 218a and the center portions 218b Therefore, temperature decrease can be further prevented at the center portion 218b of the uppermost susceptor 218H and the center portion 218b of the lowermost susceptor 218L adjacent to the dummy susceptors DMY1 to DMY4

(6) In the current embodiment 1, since the dummy susceptors DMY1 to DMY4 do not have stepped parts 218c and are flat, corner parts 218d of other susceptors 218 on which stress can be easily concentrated due to a structural reason are not formed on the dummy susceptors DMY1 to DMY4, and thus breakage of the dummy susceptors DMY1 to DMY4 caused by stress concentration can be prevented. In addition, as described above, since the temperature of the center portions 218b of the dummy susceptors DMY1 to DMY4 can be increased, stress concentration caused by the temperature difference between the peripheral portions 218a and the center portions 218b can be prevented.

In the current embodiment 1, an explanation has been given on the case where two dummy susceptors DMY1 and DMY2 are disposed above the uppermost susceptor 218H and two dummy susceptors DMY3 and DMY4 are disposed under the lowermost susceptor 218L. However, the technical ideas of the current embodiment 1 are not limited thereto. For example, notable effects of the current embodiment 1 can be attained although the current embodiment 1 is applied to other cases such as a case where at least one dummy susceptor is disposed above the uppermost susceptor 218H, a case where at least one dummy susceptor is disposed under the lowermost susceptor 218L, and a case where at least one dummy susceptor is disposed above the uppermost susceptor 218H and at least one dummy susceptor is disposed under the lowermost susceptor 218L.

Next, an explanation will be given on a substrate manufacturing process performed by using the substrate processing apparatus 101 of the current embodiment 1. Specifically, in the following description of the current embodiment 1, an explanation will be given on a method of forming semiconductor films such as silicon (Si) films on substrates such as wafers 200 by using an epitaxial growth method in one of substrate manufacturing processes. In the following description, the controller 240 controls each part of the substrate processing apparatus 101 of the current embodiment 1.

If a plurality of susceptors 218 on which wafers 200 are held are charged in the boat 217, as shown in FIG. 5, the boat 217 in which the susceptors 218 are charged is loaded into the process chamber 201 by ascending actions of the elevating table 249 and the elevating shaft 250 driven by the elevating motor 248 (boat loading). In this state, the bottom side of the manifold 209 is sealed by the seal cap 219 with the O-ring being disposed therebetween. Here, in the boat 217, dummy susceptors are charged above the uppermost susceptor 218, and dummy susceptors are charged under the lowermost susceptors 218.

Specifically, in a state where the wafers 200 are accommodated on the center portions of the susceptors 218 which are thinner than the peripheral portions of the susceptors 218, the susceptors 218 are held in the boat 217 at predetermined intervals in the extending direction of the process furnace 202 configured to process substrates therein, and along with this, the dummy susceptors having the same thickness at their center and peripheral portions are held in the boat 217 above and under the uppermost and lowermost susceptors 218 of the boat 217 at predetermined intervals from the uppermost and lowermost susceptors 218. In this state, the boat 217 is carried into the process furnace 202.

Next, the inside of the process chamber 201 is vacuum-evacuated by the vacuum exhaust device 246 to a predetermined pressure. At this time, the pressure inside the process chamber 201 is measured by the pressure sensor, and based on the measured pressure, the APC valve (pressure regular) 242 is feedback-controlled. For example, the predetermined pressure is selected from the range of 13300 Pa to 0.1 MPa. Then, the blower 2065 is operated to circulate gas or air between the induction heating device 206 and the outer tube 205 for cooling the sidewall of the outer tube 205, the gas supply chamber 2321, the gas supply holes 2322, and the gas exhaust outlet 2311. Cooling water is circulated as a cooling medium in the radiator 2064 and the cooling wall 2063 to cool the inside of the induction heating device 206 through the wall part 2062. In addition, for heating the wafers 200 to a desired temperature, a high-frequency current is applied to the induction heating device 206 to generate induction currents (eddy currents) in the susceptors 218.

In detail, at least the susceptors 218 and the dummy susceptors held by the boat 217 in the process furnace 202 are induction-heated by the induction heating device 206 so as to heat the wafers 200 accommodated on the susceptors 218.

At this time, although the amount of heat radiation from the uppermost susceptor 218 or the lowermost susceptor 218 is generally greater than the amount of heat radiation from a susceptor 218 disposed in the center portion of the boat 217, supplemental heat is provided to the uppermost susceptor 218 or the lowermost susceptor 218 by induction heating of the dummy susceptors. Therefore, the temperature of the susceptors 218 can be uniformly maintained regardless of whether the position of the susceptor 218 is the center portion, the uppermost stage, or the lowermost stage of the boat 217.

At this time, to obtain desired temperature distribution inside the process chamber 201, power to the induction heating device 206 is feedback-controlled based on temperature information measured by the radiation thermometers 263. In addition, at this time, the blower 2065 is controlled according to preset control values so as to cool the sidewall of the outer tube 205, the gas supply chamber 2321, the gas supply holes 2322, and the gas exhaust outlet 2311 to a temperature much lower than a temperature at which films are formed on the wafers 200, for example, to a temperature of 600° C. or lower. For example, the wafers 200 are heated to 1100° C. The wafers 200 are heated to a constant process temperature selected in the range from 700° C. to 1200° C. At this time, although the wafers 200 are heated to any process temperature, the sidewall of the outer tube 205, the gas supply chamber 2321, the gas supply holes 2322, and the gas exhaust outlet 2311 are cooled to a temperature much lower than a temperature at which films are formed on the wafers 200, for example, to a temperature of 600° C. or lower by controlling the blower 2065 according to preset control values.

Next, the boat 217 is rotated by using the rotary mechanism 254 to rotate the susceptors 218 and the wafers 200 held on the susceptors 218.

A Si-based and SiGe (silicon germanium)-based process gas such as SiH₄ (silane), Si₂H₆ (disilane), SiH₂Cl₂ (dichlorosilane), SiHCl₃ (trichlorosilane), and SiCl₄ (tetrachlorosilane); a doping gas such as B₂H₆ (diborane), BCl₃ (boron trichloride), and PH₃ (phosphine); a carrier gas such as hydrogen (H₂) are contained in the first gas supply source 180, the second gas supply source 181, and the third gas supply source 182, respectively. If the temperature of the wafers 200 is stabilized, process gases are supplied from the first gas supply source 180, the second gas supply source 181, and the third gas supply source 182. After adjusting the degrees of opening of the MFCs 183, 184, and 185 to obtain desired flow rates, the valves 177, 178, and 179 are opened. By this, the process gases are introduced into the gas supply chamber 2321 through the gas supply pipe 232. Since the flow passage sectional area of the gas supply chamber 2321 is sufficiently larger than the opened areas of the gas supply holes 2322, the pressure of the gas supply chamber 2321 is higher than that of the process chamber 201, and thus the process gases can be ejected into the process chamber 201 through the respective gas supply holes 2322 at a uniform flow rate and flow velocity. The process gases supplied into the process chamber 201 are allowed to flow in the process chamber 201 and are discharged to the gas exhaust outlet 2311. Then, the process gases are exhausted from the gas exhaust outlet 2311 to the gas exhaust pipe 231. When the process gases flow through gaps between the susceptors 218, the process gases are heated by upper and lower susceptors 218, and at the same time, the process gases make contact with the heated wafers 200 so that semiconductor films such as silicon (Si) films may be epitaxially formed on the surface of the wafers 200.

After a predetermined time, an inert gas is supplied from an inert gas supply source (not shown) to replace the inside atmosphere of the process chamber 201 with the inert gas, and along with this, the inside pressure of the process chamber 201 is returned to normal pressure.

Thereafter, the seal cap 219 is lowered by the elevating motor 248 to open the bottom side of the manifold 209 and unload the boat 217 in which the processed wafers 200 are held to the outside of the outer tube 205 through the bottom side of the manifold 209 (boat unloading). Then, the processed wafers 200 are discharged from the boat 217 (wafer discharging). In this way, semiconductor films are formed on the wafers 200.

### Embodiment 2

In the embodiment 1, the thickness of the peripheral portions 218a of the ordinary susceptors 218 configured to load wafers 200 thereon is equal to the thickness of the dummy susceptors DMY1 to DMY4. However, in the current embodiment 2, the thickness of dummy susceptors DMY1 to DMY4 is greater than the thickness of peripheral portions 218a of ordinary susceptors 218 configured to load wafers 200 thereon. The other configurations are the same as those of the embodiment 1.

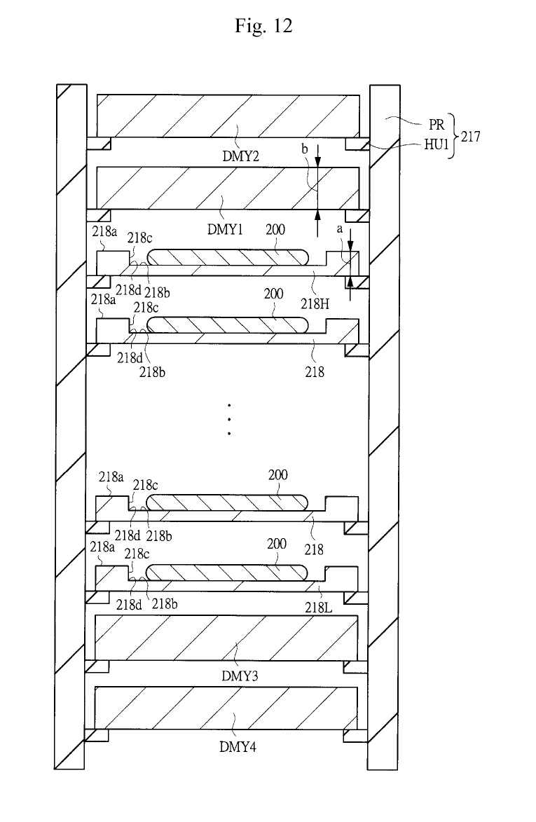

FIG. 12 is a sectional view illustrating a state where susceptors 218 on which wafers 200 are held are charged in a boat 217 of a substrate processing apparatus of the current embodiment 2. As shown in FIG. 12, a boat 217 includes: a plurality of pillars PR extending in the extending direction of the boat 217 (the vertical direction in FIG. 12); and holding parts HU1 installed on each of the pillars PR at regular intervals in the extending direction. The holding parts HU1 are installed at the same heights of the pillars PR, and end parts of a susceptor 218 is held by two holding parts HU1 installed at the same height. Therefore, the susceptor 218 held by the two holding parts HU1 can be horizontally disposed. In detail, as shown in FIG. 12, susceptors 218 are respectively loaded on the holding parts HU1 arranged at predetermined intervals in the extending direction of the boat 217. That is, in the boat 217, a plurality of susceptors 218 are stacked at predetermined intervals in the extending direction of the boat 217. In this way, the susceptors 218 are provided independent of the pillars PR in a manner such that the susceptors 218 can be charged in the boat 217 and discharged from the boat 217.

Referring to FIG. 12, among the susceptors 218 on which the wafers 200 are loaded, one disposed on the uppermost stage is referred as a susceptor 218H, and one disposed on the lowermost stage is referred as a susceptor 218L. At this time, dummy susceptors DMY1 and DMY2 are disposed above the uppermost susceptor 218H, and dummy susceptors DMY3 and DMY4 are disposed under the lowermost susceptor 218L.

The current embodiment 2 is characterized in that the thickness (b) of the dummy susceptors DMY1 and DMY2 disposed above the susceptor 218H is greater than the thickness of the peripheral portion 218a of the susceptor 218H. That is, the thickness of peripheral portions of the dummy susceptors DMY1 and DMY2 which are second induction target parts is greater than the thickness of the peripheral portion 218a of the susceptor 218H which is a first induction target part.

Similarly, the thickness (b) of the dummy susceptors DMY3 and DMY4 disposed under the susceptor 218L is greater than the thickness of the peripheral portion 218a of the susceptor 218L. That is, the thickness of peripheral portions of the dummy susceptors DMY3 and DMY4 which are second induction target parts is greater than the thickness of the peripheral portion 218a of the susceptor 218L which is a first induction target part.

Therefore, temperature decrease can be prevented at a center portion 218b of the uppermost susceptor 218H disposed close to the dummy susceptor DMY1, and temperature decrease can be prevented at a center portion 218b of the lowermost susceptor 218L disposed close to the dummy susceptor DMY3. Generally, no susceptor is provided above the dummy susceptors DMY1 and DMY2 disposed above the susceptor 218H which is placed on the uppermost stage among the susceptors 218 on which wafers 200 are held, and no susceptor is provided under the dummy susceptors DMY3 and DMY4 disposed under the susceptor 218L which is placed on the lowermost stage among the susceptors 218 on which wafers 200 are held. Therefore, the amounts of heat radiation at the topsides of the dummy susceptors DMY1 and DMY2 and the bottom sides of the dummy susceptors DMY3 and DMY4 may be relatively great, and thus the temperature of the dummy susceptors DMY1 to DMY4 may be relatively low. Due to this, the temperature of the uppermost susceptor 218H and the lowermost susceptor 218L close to the dummy susceptor DMY1 and the dummy susceptor DMY3 may also be low. However, according to the current embodiment 2, the thickness of the dummy susceptors DMY1 to DMY4 is greater than the thickness of the uppermost susceptor 218H and the lowermost susceptor 218L, and thus the heat capacities of the dummy susceptors DMY1 to DMY4 can be increased. In addition, the strength of the dummy susceptors DMY1 to DMY4 can be increased. Therefore, according to the current embodiment 2, the thickness of the dummy susceptors DMY1 to DMY4 is set to be greater than the thickness of the uppermost susceptor 218H and the lowermost susceptor 218L, for example, in a factor of 1.5 times, so as to suppress heat radiation at the topsides of the dummy susceptors DMY1 and DMY2 and the bottom sides of the dummy susceptors DMY3 and DMY4. As a result, since the temperature of the dummy susceptors DMY1 to DMY4, particularly, the temperature of the center portions of the dummy susceptors DMY1 to DMY4 can be kept high, the temperature of the center portions 218b of the uppermost susceptor 218H and the lowermost susceptor 218L close to the dummy susceptors DMY1 and DMY3 can be kept high.

### Embodiment 3

In the following description of the embodiment 3, an explanation will be given on an exemplary case where center portions CE1 of dummy susceptors DMY1 to DMY4 are thinner than peripheral portions FR1 of the dummy susceptors DMY1 to DMY4 and sloped parts SLP1 are formed between the center portions CE1 and the peripheral portions FR1. The other configurations are the same as those of the embodiment 1.

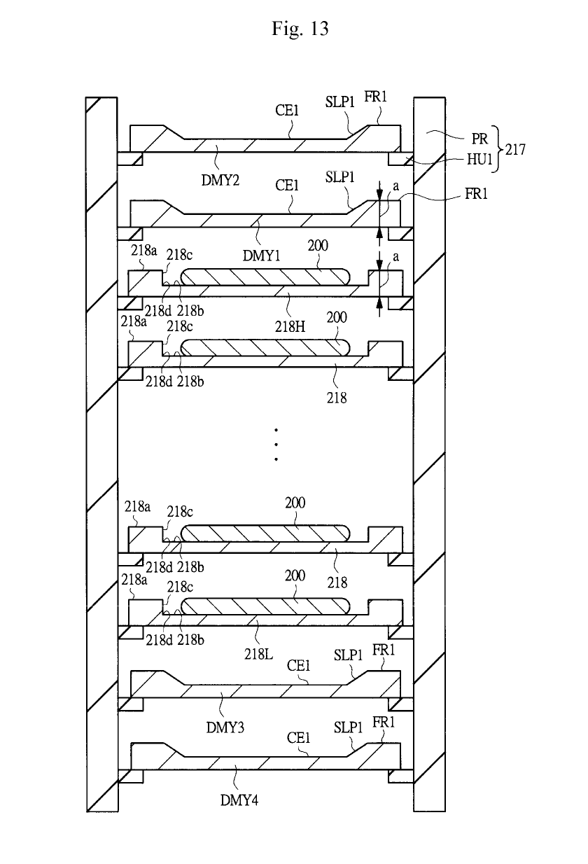

FIG. 13 is a sectional view illustrating a state where susceptors 218 on which wafers 200 are held are charged in a boat 217 of a substrate processing apparatus of the current embodiment 3. As shown in FIG. 13, the boat 217 includes: a plurality of pillars PR extending in the extending direction of the boat 217 (the vertical direction in FIG. 13); and holding parts HU1 installed on each of the pillars PR at regular intervals in the extending direction. The holding parts HU1 are installed at the same heights of the pillars PR, and end parts of a susceptor 218 is held by two holding parts HU1 installed at the same height. Therefore, the susceptor 218 held by the two holding parts HU1 can be horizontally disposed. In detail, as shown in FIG. 13, the susceptors 218 are respectively loaded on the holding parts HU1 arranged at predetermined intervals in the extending direction of the boat 217. That is, in the boat 217, a plurality of susceptors 218 are stacked at predetermined intervals in the extending direction of the boat 217. In this way, the susceptors 218 are provided independent of the pillars PR in a manner such that the susceptors 218 can be charged in the boat 217 and discharged from the boat 217.

Referring to FIG. 13, among the susceptors 218 on which the wafers 200 are loaded, one disposed on the uppermost stage is referred as a susceptor 218H, and one disposed on the lowermost stage is referred as a susceptor 218L. At this time, the dummy susceptors DMY1 and DMY2 are disposed above the uppermost susceptor 218H, and the dummy susceptors DMY3 and DMY4 are disposed under the lowermost susceptor 218L. It may be preferable that the thickness of the peripheral portions FR1 of the dummy susceptors DMY1 to DMY4 is set to be equal to the thickness of peripheral portions 218a of the susceptors 218.

The current embodiment 3 is characterized by the following facts. In the dummy susceptors DMY1 and DMY2 disposed above the uppermost susceptor 218H, the thickness of the center portions CE1 is set to be smaller than the thickness of the peripheral portions FR1, and the sloped parts SLP1 are formed between the center portions CE1 and the peripheral portions FR1. That is, the center portions CE1 of the dummy susceptors DMY1 and DMY2 are thinner than the peripheral portions FR1 of the dummy susceptors DMY1 and DMY2, and the thickness of boundary portions between the center portions CE1 and the peripheral portions FR1 is gradually decreased in an inward direction.

Similarly, in the dummy susceptors DMY3 and DMY4 disposed under the lowermost susceptor 218L, the thickness of the center portions CE1 is set to be smaller than the thickness of the peripheral portions FR1, and the sloped parts SLP1 are formed between the center portions CE1 and the peripheral portions FR1. That is, the center portions CE1 of the dummy susceptors DMY3 and DMY4 are thinner than the peripheral portions FR1 of the dummy susceptors DMY3 and DMY4, and the thickness of boundary portions between the center portions CE1 and the peripheral portions FR1 is gradually decreased in an inward direction.

By this, breakage of the dummy susceptors DMY1 to DMY4 can be suppressed. For example, if the dummy susceptors DMY1 to and DMY4 have the same shape as the susceptors 218, vertically stepped parts are formed between the center portions CE1 and the peripheral portions FR1.

Since no susceptor is disposed above the dummy susceptor DMY2 and under the dummy susceptor DMY4, the amount of heat radiation from the dummy susceptors DMY1 to DMY4 is large. Particularly, although the peripheral portions FR1 of the dummy susceptors DMY1 to DMY4 are heated by induced eddy currents, the center portions CE1 of the dummy susceptors DMY1 to DMY4 are not easily induction-heated because eddy currents are not easily generated in the center portions CE1. Therefore, in the dummy susceptors DMY1 to DMY4, the temperature difference between the center portions CE1 and the peripheral portions FR1 is significantly large. Thus, if the dummy susceptors DMY1 to DMY4 have the same shape as that of the susceptors 218, the dummy susceptors DMY1 to DMY4 may be broken due to stress concentration on the vertically stepped parts of the dummy susceptors DMY1 to DMY4.

Therefore, in the dummy susceptors DMY1 to DMY4 of the current embodiment 3, the sloped parts SLP1 are formed between the center portions CE1 and the peripheral portions FR1. In this way, if the generally sloped parts SLP1 are formed between the center portions CE1 an the peripheral portions FR1, structural stress concentration and thermal stress concentration can be reduced at the generally sloped parts SLP1 as compared with the case where vertically stepped steep parts are formed between the center portions CE1 and the peripheral portions FR1. Therefore, breakage of the dummy susceptors DMY1 to DMY4 can be suppressed.

### Embodiment 4

In the following description of the embodiment 4, an explanation will be given on an exemplary case where center portions CE1 of dummy susceptors DMY1 to DMY4 are thicker than peripheral portions FR1 of the dummy susceptors DMY1 to DMY4. The other configurations are the same as those of the embodiment 1.

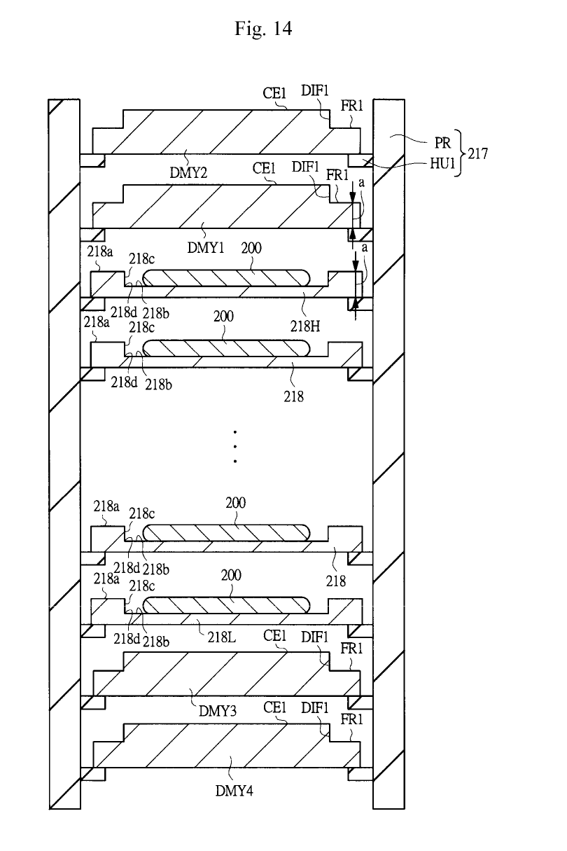

FIG. 14 is a sectional view illustrating a state where susceptors 218 on which wafers 200 are held are charged in a boat 217 of an substrate processing apparatus of the current embodiment 4. As shown in FIG. 14, the boat 217 includes: a plurality of pillars PR extending in the extending direction of the boat 217 (the vertical direction in FIG. 14); and holding parts HU1 installed on each of the pillars PR at regular intervals in the extending direction. The holding parts HU1 are installed at the same heights of the pillars PR, and end parts of a susceptor 218 is held by two holding parts HU1 installed at the same height. Therefore, the susceptor 218 held by the two holding parts HU1 can be horizontally disposed. In detail, as shown in FIG. 14, susceptors 218 are respectively loaded on the holding parts HU1 arranged at predetermined intervals in the extending direction of the boat 217. That is, in the boat 217, a plurality of susceptors 218 are stacked at predetermined intervals in the extending direction of the boat 217. In this way, the susceptors 218 are provided independent of the pillars PR in a manner such that the susceptors 218 can be charged in the boat 217 and discharged from the boat 217.

Referring to FIG. 14, among the susceptors 218 on which the wafers 200 are loaded, one disposed on the uppermost stage is referred as a susceptor 218H, and one disposed on the lowermost stage is referred as a susceptor 218L. At this time, the dummy susceptors DMY1 and DMY2 are disposed above the uppermost susceptor 218H, and the dummy susceptors DMY3 and DMY4 are disposed under the lowermost susceptor 218L.

The current embodiment 4 is characterized in that the center portions CE1 of the dummy susceptors DMY1 to DMY4 are thicker than the peripheral portions FR1 of the dummy susceptors DMY1 to DMY4. Preferably, the dummy susceptors DMY1 and DMY2 may have the same diameter as the susceptors 218; the peripheral portions FR1 of the dummy susceptors DMY1 and DMY2 may have the same thickness as peripheral portions 218a of the susceptors 218; and the center portions CE1 of the dummy susceptors DMY1 and DMY2 may have a protruded shape. More preferably, the center portions CE1 of the dummy susceptors DMY1 and DMY2 may be thicker than the peripheral portions FR1 of the dummy susceptors DMY1 and DMY2, and the outer diameter of boundary portions (stepped parts DIF1) between the center portions CE1 and the peripheral portions FR1 of the dummy susceptors DMY1 and DMY2 may be equal to or greater than the inner diameter of boundary portions between the peripheral portions 218a and center portion 218b of the susceptors 218.

In addition, preferably, the dummy susceptors DMY3 and DMY4 disposed under the lowermost susceptor 218L may be configured as follows: the dummy susceptors DMY3 and DMY4 have the same diameter as the susceptors 218; the peripheral portions FR1 of the dummy susceptors DMY3 and DMY4 have the same thickness as the peripheral portions 218a of the susceptors 218; and the center portions CE1 of the dummy susceptors DMY3 and DMY4 have a protruded shape. More preferably, the center portions CE1 of the dummy susceptors DMY3 and DMY4 may be thicker than the peripheral portions FR1 of the dummy susceptors DMY3 and DMY4, and the outer diameter of boundary portions (stepped parts DIF1) between the center portions CE1 and the peripheral portions FR1 of the dummy susceptors DMY3 and DMY4 may be equal to or greater than the inner diameter of boundary portions between the peripheral portions 218a and center portion 218b of the susceptors 218.

Therefore, temperature decrease can be prevented at the center portion 218b of the uppermost susceptor 218H disposed close to the dummy susceptor DMY1, and temperature decrease can be prevented at the center portion 218b of the lowermost susceptor 218L disposed close to the dummy susceptor DMY3. Particularly, in the current embodiment 4, since the center portions CE1 of the dummy susceptors DMY1 to DMY4 are thicker than the peripheral portions FR1 of the dummy susceptors DMY3 and DMY4, the stepped parts DIF1 can receive a high-frequency electromagnetic field generated from an inductor (RF coil). That is, in the current embodiment 4, since the center portions CE1 of the dummy susceptors DMY1 to DMY4 have a protruded shape, the protruded center portions CE1 can be easily induction-heated. As a result, since the temperature of the center portions CE1 of the dummy susceptors DMY1 to DMY4 can be more increased, the temperature of the center portions 218b of the uppermost susceptor 218H and the lowermost susceptor 218L close to the dummy susceptors DMY1 and DMY3 can also be kept high.

In addition, according to the current embodiment 4, since the temperature of the center portions CE1 of the dummy susceptors DMY1 to DMY4 can be kept high, the temperature difference between the peripheral portions FR1 and the center portions CE1 of the dummy susceptors DMY1 to DMY4 can be reduced.

Thus, stress concentration caused by temperature difference can be reduced at the boundary regions between the peripheral portions FR1 and the center portions CE1. As a result, breakage of the dummy susceptors DMY1 to DMY4 can be suppressed, and generation of contaminants can be suppressed.

### Embodiment 5

In the following description of the embodiment 5, an explanation will be given on an exemplary case where center portions CE1 of dummy susceptors DMY1 to DMY4 are thicker than peripheral portions FR1 of the dummy susceptors DMY1 to DMY4 and sloped parts SLP2 are formed between the center portions CE1 and the peripheral portions FR1. The other configurations are the same as those of the embodiment 4.

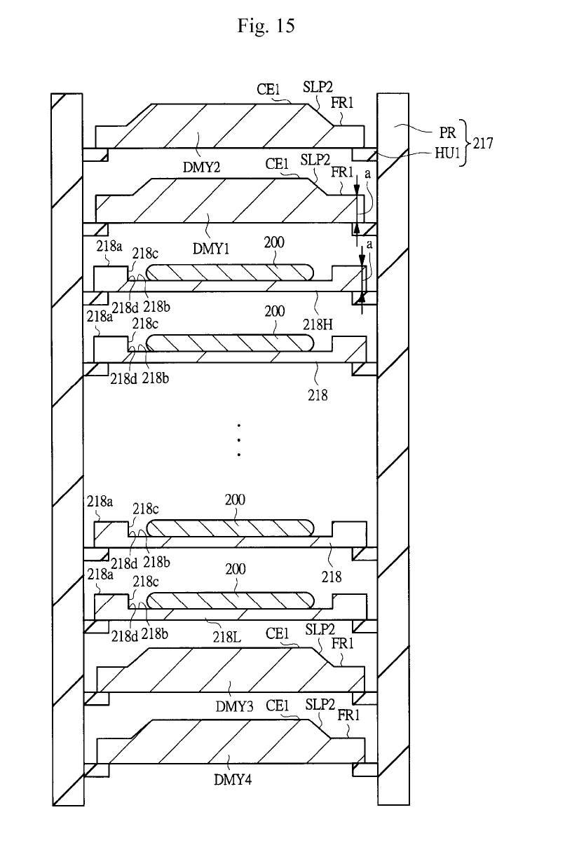

Referring to FIG. 15, in a substrate processing apparatus of the current embodiment 5, one disposed on the uppermost stage among susceptors 218 on which the wafers 200 are loaded is referred as a susceptor 218H, and one disposed on the lowermost stage is referred as a susceptor 218L. At this time, the dummy susceptors DMY1 and DMY2 are disposed above the uppermost susceptor 218H, and the dummy susceptors DMY3 and DMY4 are disposed under the lowermost susceptor 218L.

The current embodiment 5 is characterized in that the center portions CE1 of the dummy susceptors DMY1 to DMY4 are thicker than the peripheral portions FR1 of the dummy susceptors DMY1 to DMY4 and the sloped parts SLP2 are formed between the center portions CE1 and the peripheral portions FR1. Preferably, the dummy susceptors DMY1 and DMY2 may have the same diameter as the susceptors 218; the peripheral portions FR1 of the dummy susceptors DMY1 and DMY2 may have the same thickness as peripheral portions 218a of the susceptors 218; the center portions CE1 of the dummy susceptors DMY1 and DMY2 may have a protruded shape; and the sloped parts SLP2 may be formed at boundary portions between the center portions CE1 and the peripheral portions FR1 of the dummy susceptors DMY1 and DMY2. More preferably, the center portions CE1 may be thicker than the peripheral portions FR1; the thickness of the boundary portions between the center portions CE1 and the peripheral portions FR1 may be gradually increased in an inward direction; and the outer diameter of the boundary portions of the dummy susceptors DMY1 and DMY2 may be equal to or greater than the inner diameter of boundary portions between the peripheral portions 218a and center portion 218b of the susceptors 218.

In addition, preferably, the dummy susceptors DMY3 and DMY4 disposed under the lowermost susceptor 218L may have the same diameter as the susceptors 218; the peripheral portions FR1 of the dummy susceptors DMY3 and DMY4 may have the same thickness as the peripheral portions 218a of the susceptors 218; the center portions CE1 of the dummy susceptors DMY3 and DMY4 may have a protruded shape; and the sloped parts SLP2 may be formed between the center portions CE1 and the peripheral portions FR1 of the dummy susceptors DMY3 and DMY4. More preferably, the center portions CE1 may be thicker than the peripheral portions FR1; the thickness of the boundary portions between the center portions CE1 and the peripheral portions FR1 may be gradually increased in an inward direction; and the outer diameter of the boundary portions of the dummy susceptors DMY3 and DMY4 may be equal to or greater than the inner diameter of the boundary portions between the peripheral portions 218a and center portion 218b of the susceptors 218.

Therefore, temperature decrease can be prevented at the center portion 218b of the uppermost susceptor 218H disposed close to the dummy susceptor DMY1, and temperature decrease can be prevented at the center portion 218b of the lowermost susceptor 218L disposed close to the dummy susceptor DMY3.

Particularly, in the current embodiment 5, the sloped parts SLP2 are formed in the boundary regions between the peripheral portions FR1 and the center portions CE1 of the dummy susceptors DMY1 to DMY4. In this way, if the generally sloped parts SLP2 are formed between the center portions CE1 an the peripheral portions FR1, stress concentration can be reduced at the generally sloped parts SLP2 as compared with the case where vertically stepped steep parts are formed between the center portions CE1 and the peripheral portions FR1. Thus, stress concentration caused by temperature difference can be reduced at the boundary regions between the peripheral portions FR1 and the center portions CE1. As a result, breakage of the dummy susceptors DMY1 to DMY4 can be suppressed, and generation of contaminants can be suppressed.

### Embodiment 6

In the following description of the embodiment 6, an explanation will be given on an exemplary case where center portions CE2 of dummy susceptors DMY1 to DMY4 are thicker than peripheral portions FR2 of the dummy susceptors DMY1 to DMY4 and the center portions CE2 has a diameter smaller than that of wafers 200. The other configurations are the same as those of the embodiment 5.

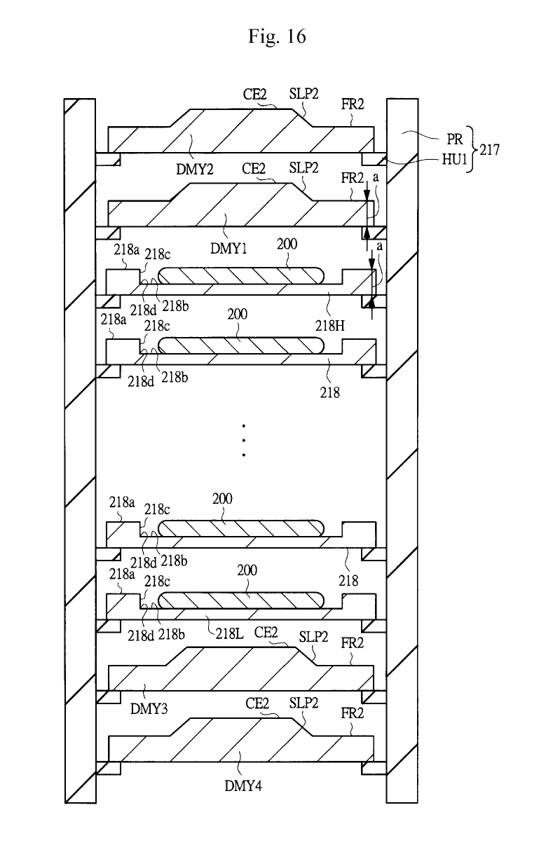

Referring to FIG. 16, in a substrate processing apparatus of the current embodiment 6, one disposed on the uppermost stage among susceptors 218 on which the wafers 200 are loaded is referred as a susceptor 218H, and one disposed on the lowermost stage is referred as a susceptor 218L. At this time, the dummy susceptors DMY1 and DMY2 are disposed above the uppermost susceptor 218H, and the dummy susceptors DMY3 and DMY4 are disposed under the lowermost susceptor 218L.

The current embodiment 6 is characterized in that where the center portions CE2 of the dummy susceptors DMY1 to DMY4 are thicker than the peripheral portions FR2 of the dummy susceptors DMY1 to DMY4 and the center portions CE2 has a diameter smaller than that of wafers 200. Preferably, the dummy susceptors DMY1 and DMY2 disposed above the uppermost susceptor 218H may have the same diameter as the susceptors 218; the peripheral portions FR2 of the dummy susceptors DMY1 and DMY2 may have the same thickness as peripheral portions 218a of the susceptors 218; the center portions CE2 having a diameter smaller than that of wafers 200 may have a protruded shape; and the sloped parts SLP2 may be formed between the center portions CE2 and the peripheral portions FR2 of the dummy susceptors DMY1 and DMY2. More preferably, the center portions CE2 may be thicker than the peripheral portions FR2; the thickness of boundary portions between the center portions CE2 and the peripheral portions FR2 may be gradually increased in an inward direction; and the outer diameter of the boundary portions of the dummy susceptors DMY1 and DMY2 may be smaller than the inner diameter of boundary portions between the peripheral portions 218a and center portion 218b of the susceptors 218.

In addition, preferably, the dummy susceptors DMY3 and DMY4 disposed under the lowermost susceptor 218L may have the same diameter as the susceptors 218; the peripheral portions FR2 of the dummy susceptors DMY3 and DMY4 may have the same thickness as the peripheral portions 218a of the susceptors 218; the center portions CE2 having a diameter smaller than that of wafers 200 may have a protruded shape; and the sloped parts SLP2 may be formed between the center portions CE2 and the peripheral portions FR2 of the dummy susceptors DMY3 and DMY4. More preferably, the center portions CE2 may be thicker than the peripheral portions FR2; the thickness of boundary portions between the center portions CE2 and the peripheral portions FR2 may be gradually increased in an inward direction; and the outer diameter of the boundary portions of the dummy susceptors DMY3 and DMY4 may be smaller than the inner diameter of the boundary portions between the peripheral portions 218a and center portion 218b of the susceptors 218.

Therefore, temperature decrease can be prevented at the center portion 218b of the uppermost susceptor 218H disposed close to the dummy susceptor DMY1, and temperature decrease can be prevented at the center portion 218b of the lowermost susceptor 218L disposed close to the dummy susceptor DMY3. Particularly, since the center portions CE2 of the dummy susceptors DMY1 to DMY4 have a diameter smaller than that of wafers 200 and are formed into a protruded shape, the temperature of the center portions CE2 of the dummy susceptors DMY1 to DMY4 can be further increased. That is, in the current embodiment 6, since the center portions CE2 of the dummy susceptors DMY1 to DMY4 have a diameter smaller than that of wafers 200 and are formed into a protruded shape, the protruded center portions CE2 can be induction-heated. As a result, since the temperature of the center portions CE2 of the dummy susceptors DMY1 to DMY4 can be more increased, the temperature of the center portions 218b of the uppermost susceptor 218H and the lowermost susceptor 218L close to the dummy susceptors DMY1 and DMY3 can also be kept high.

In addition, according to the current embodiment 6, for the case where the susceptors 218 and the dummy susceptors DMY1 to DMY4 are charged into and discharged from a boat 217 by picking up them from the bottom sides thereof, the thickness of the peripheral portions FR2 of the dummy susceptors DMY1 to DMY4 is set to be equal to the thickness of the peripheral portions 218a of the susceptors 218, and the diameter of the protruded shape of the center portions CE2 of the dummy susceptors DMY1 to DMY4 is set to be smaller than the diameter of wafers 200. Therefore, according to the dummy susceptors DMY1 to DMY4 of the current embodiment 6, sufficient picking-up area ensuring effect can be attained.

### Embodiment 7

In the following description of the embodiment 7, an explanation will be given on an exemplary case where dummy susceptors DMY1 and DMY3 closer to susceptors 218 than dummy susceptors DMY2 and DMY4 are formed into a stronger shape against damage than the dummy susceptors DMY2 and DMY4. The other configurations are the same as those of the embodiments 1 and 6.

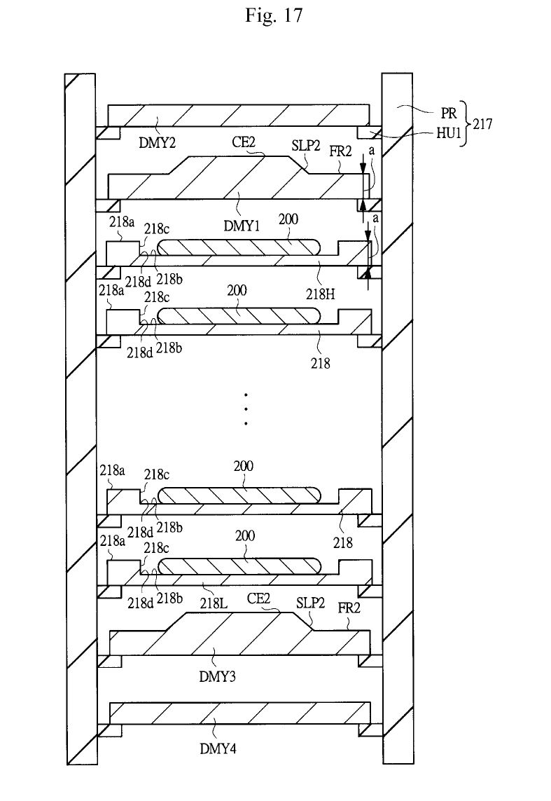

Referring to FIG. 17, in a substrate processing apparatus of the current embodiment 7, one disposed on the uppermost stage among susceptors 218 on which the wafers 200 are loaded is referred as a susceptor 218H, and one disposed on the lowermost stage is referred as a susceptor 218L. At this time, the dummy susceptors DMY1 and DMY2 are disposed above the uppermost susceptor 218H, and the dummy susceptors DMY3 and DMY4 are disposed under the lowermost susceptor 218L.

The current embodiment 7 is characterized in that the dummy susceptors DMY1 and DMY2 have different shapes and are disposed above the susceptor 218H. In detail, a center portion CE2 of the dummy susceptor DMY1 is thicker than a peripheral portion FR2 of the dummy susceptors DMY1, and the dummy susceptor DMY2 has a flat shape. Preferably, the dummy susceptor DMY1 may be configured such that: the diameter of the dummy susceptor DMY1 is equal to the diameter of the ordinary susceptors 218 on which wafers 200 are held; the thickness of the peripheral portion FR2 is equal to the thickness of the peripheral portions 218a of the ordinary susceptors 218; the center portion CE2 has a diameter smaller than that of wafers 200 and is formed into a protruded shape; and a sloped part SLP2 is formed between the peripheral portion FR2 and the center portion CE2. On the other hand, preferably, the dummy susceptor DMY2 disposed above the dummy susceptor DMY1 may be configured such that: the diameter of the dummy susceptor DMY2 is equal to the diameter of the ordinary susceptors 218 on which wafers 200 are held; the thickness of the dummy susceptor DMY2 is equal to the thickness of the peripheral portion FR2; and the dummy susceptor DMY2 has a flat shape.

In addition, the current embodiment 7 is characterized in that the dummy susceptors DMY3 and DMY4 have different shapes and are disposed under the susceptor 218L. In detail, a center portion CE2 of the dummy susceptor DMY3 is thicker than a peripheral portion FR2 of the dummy susceptors DMY3, and the dummy susceptor DMY4 has a flat shape. Preferably, the dummy susceptor DMY3 may be configured such that: the diameter of the dummy susceptor DMY3 is equal to the diameter of the ordinary susceptors 218 on which wafers 200 are held; the thickness of the peripheral portion FR2 is equal to the thickness of the peripheral portions 218a of the ordinary susceptors 218; the center portion CE2 has a diameter smaller than that of wafers 200 and is formed into a protruded shape; and a sloped part SLP2 is formed between the peripheral portion FR2 and the center portion CE2. On the other hand, preferably, the dummy susceptor DMY4 disposed under the dummy susceptor DMY3 may be configured such that: the diameter of the dummy susceptor DMY4 is equal to the diameter of the ordinary susceptors 218 on which wafers 200 are held; the thickness of the dummy susceptor DMY4 is equal to the thickness of the peripheral portion FR2; and the dummy susceptor DMY4 has a flat shape.

For example, since the center portion CE2 of the dummy susceptors DMY1 disposed above the susceptor 218H is formed into a protruded shape, the side surface of the protruded shape can receive a high-frequency electromagnetic field from an inductor (RF coil). That is, in the current embodiment 7, since the center portions CE2 of the dummy susceptor DMY1 has a protruded shape, the protruded center portion CE2 can be induction-heated. As a result, since the temperature of the center portion CE2 of the dummy susceptor DMY1 can be more increased, the temperature of a center portion 218b of the uppermost susceptor 218H close to the dummy susceptor DMY1 can also be kept high.

The dummy susceptor DMY2 is disposed above the dummy susceptor DMY1. The dummy susceptor DMY2 is disposed on the uppermost stage of a boat 217. Since the dummy susceptor DMY2 is disposed on the uppermost stage of the boat 217, the amount of heat radiation from a center portion of the dummy susceptor DMY2 is great, and thus the temperature difference between center and peripheral portions of the dummy susceptor DMY2 is great. That is, since the susceptors 218H is disposed under the dummy susceptor DMY1 and the dummy susceptor DMY2 is disposed above the dummy susceptor DMY1, heat radiation from the center portion CE2 of the dummy susceptor DMY1 can be reduced. However, since nothing is disposed above the dummy susceptor DMY2, the amount of heat radiation from the center portion of the dummy susceptor DMY2 is large.

That is, the temperature difference between the center and peripheral portions of the dummy susceptor DMY2 disposed on the uppermost stage of the boat 217 is greater than the temperature difference between the peripheral portion FR2 and the center portion CE2 of the dummy susceptor DMY1 disposed under the dummy susceptor DMY2. Therefore, relatively greater stress may be imposed on the dummy susceptor DMY2 as compared with the dummy susceptor DMY1.

Therefore, if the dummy susceptor DMY2 has a protruded center portion like the dummy susceptor DMY1, more stress is imposed on the boundary region between the center and peripheral portions of the dummy susceptor DMY2. In this case, the dummy susceptor DMY2 may be broken or contaminants may be generated.

Thus, according to the current embodiment 7, since the temperature difference between the center and peripheral portions of the dummy susceptor DMY2 can be highest, the dummy susceptor DMY2 is not formed in a concave-convex shape but is formed in a flat shape. In this case, the dummy susceptor DMY2 can have improved structural strength but dose not have a stress-concentration point. In addition, although the temperature difference between the peripheral and center portions of the dummy susceptor DMY2 is great, the dummy susceptor DMY2 may not have a stress-concentration point. That is, in the current embodiment 7, since the dummy susceptor DMY2 disposed on the uppermost stage of the boat 217 is formed into a flat shape, the temperature difference between the peripheral and center portions may be reduced, and even if the dummy susceptor DMY2 is coated with a silicon carbide film, stress concentration may not occur due to a film thickness difference. Therefore, breakage of the dummy susceptor DMY2 can be suppressed, and generation of contaminants can be suppressed.

In addition, the dummy susceptors DMY1 and DMY3 of any of the previous embodiments 2 to 5 may be applied to the dummy susceptors DMY1 and DMY3 of the current embodiment 7. Dummy susceptors having a stronger shape against damage than the dummy susceptors DMY1 and DMY3, such as the dummy susceptors DMY2 and DMY4 of any of the previous embodiments 2 to 6, may be properly applied to the dummy susceptors DMY2 and DMY4 of the current embodiment 7.

While the invention proposed by the inventors has been particularly described with reference to the embodiments, the present invention is not limited to the embodiments, but various changes and modifications may be made in the present invention without departing from the scope of the invention.

In addition, the preferable example of the embodiment 5 may be combined with the preferable example of the embodiment 6. That is, first sloped parts may be formed on the boundary portions between the center portions CE1 and the peripheral portions FR1 of the dummy susceptors DMY1 to DMY4 in a situation where the outer diameter of the boundary portions between the center portions CE1 and the peripheral portions FR1 is equal to or greater than the inner diameter of the boundary portions between the center portions 218b and the peripheral portions 218a of the susceptors 218, and second sloped parts may be formed on the boundary portions between the center portions CE1 and the peripheral portions FR1 in a situation where the outer diameter of the boundary portions between the center portions CE1 and the peripheral portions FR1 is smaller than the inner diameter of the boundary portions between the center portions 218b and the peripheral portions 218a of the susceptors 218. The thickness of the second sloped parts may be greater than that of the first sloped parts.

In the above description of the embodiments, explanations have been given on exemplary cases where a dummy susceptor is disposed above the uppermost susceptor 218. However, the technical ideas of the embodiments are not limited thereto. For example, in the case where susceptors 218 are held on upper holding parts HU1 and lower holding parts HU1 of the boat 217 but a susceptor 218 is not held on holding parts HU1 between the upper holding parts HU1 and the lower holding parts HU1, a dummy susceptor may be disposed on the holding parts HU1 where a susceptor 218 is not held. Even in this case, the remarkable effects of the previous embodiments can be attained to some degree.

Furthermore, in the above description of the embodiments, explanations have been given on exemplary cases where a plurality of susceptors 218 are disposed in the boat 217 in multiple stages. However, the technical ideas of the embodiments are not limited thereto. For example, the same remarkable effects of the embodiment 1 can be attained in the case where at least one susceptor 218 is disposed in the boat 217.

The semiconductor film forming conditions explained in the above embodiments are exemplary conditions. That is, the conditions can be changed according to situations. For example, if semiconductor films are formed by a chemical vapor deposition (CVD) method, gas such as trichlorosilane (SiHCl₃) gas may be used as a source gas, and a boron-containing gas such as diborane (B₂H₆) gas may be used as a dopant gas. In addition, hydrogen (H₂) gas may be used as a carrier gas.

In the above description of the source gas supply method, an explanation has been given on an exemplary case where the gas supply chamber is installed at the outer tube. However, if heat conduction between the outer tube and the gas supply chamber is not so necessary, a plurality of gas supply nozzles which are parts separate from the outer tube may be erected in the outer tube instead of installing the gas supply chamber. In this case, a plurality of gas supply holes may be formed through sidewalls of the gas supply nozzles.

An explanation has been given on an exemplary case where the loadlock chamber is used as a standby chamber that can be vacuum-evacuated. However, in the case of performing a process in which attachment of a natural oxide film on a substrate is not so problematic, a standby chamber that can be kept under a nitrogen gas atmosphere or a clean air atmosphere may be used instead of the loadlock chamber. In this situation, a simple case may be used instead of the pressure-resistant case.

An explanation has been given on the case where the susceptor holding mechanism includes push-up pins insertable in pin holes of a susceptor and a push-up pin elevating mechanism. However, the present invention is not limited thereto. For example, instead of using the pin holes, the push-up pins, and the push-up pin elevating mechanism, a wafer may be charged or discharged between a susceptor and tweezers by holding the wafer with the tweezers by way of attaching a surface region of the wafer that does affect film-forming characteristics to the tweezers by suction.

In addition, in the above description of the embodiments, an exemplary epitaxial apparatus has been described. However, the technical ideas of the present invention can be applied to other substrate processing apparatuses such as a chemical vapor deposition (CVD) apparatus, an atomic layer deposition (ALD) apparatus, an oxidation apparatus, a diffusion apparatus, and an annealing apparatus.

The following is a brief description of an effect that can be obtained from a representative element of the invention disclosed this application.

It is possible to prevent breakage of the induction target part of the substrate processing apparatus using an induction heating method.

The present invention can be widely used in semiconductor device manufacturing industries.

[Supplementary Note]

The present invention also includes at least the following embodiments.

[Supplementary Note 1]

According to an embodiment of the present invention, there is provided a substrate processing apparatus comprising:

a reaction vessel configured to process substrates therein;

a plurality of first induction target parts each including a peripheral portion and a center portion wherein a thickness of the center portion is less than that of the peripheral portion, the first induction target part being configured to heat the substrate accommodated on the center portion;

an induction target part holder configured to hold the plurality of first induction target parts in an extending direction of the reaction vessel;

a second induction target part held by the induction target part holder at a predetermined distance from an uppermost first induction target part or a lowermost first induction target part among the plurality of first induction target parts held by the induction target part holder in the extending direction, the second induction target including a peripheral portion and a center portion wherein a thickness of the center portion is equal to or greater than that of the peripheral portion, the second induction target part being configured to heat the substrate accommodated on the center portion of the first induction target part; and

an induction heating device configured to heat at least the plurality of first induction target parts and the second induction target part, which are provided in the reaction vessel and held by the induction target part holder by using an induction heating method.

[Supplementary Note 2]

According to another embodiment of the present invention, there is provided a substrate processing apparatus comprising:

a reaction vessel configured to process substrates therein;

a plurality of first induction target parts each including a peripheral portion and a center portion wherein a thickness of the center portion is less than that of the peripheral portion, the first induction target part being configured to heat the substrate accommodated on the center portion;

an induction target part holder configured to hold the plurality of first induction target parts in an extending direction of the reaction vessel;

a second induction target part held by the induction target part holder at a predetermined distance from an uppermost first induction target part or a lowermost first induction target part among the plurality of first induction target parts held by the induction target part holder in the extending direction, the second induction target including a peripheral portion and a center portion wherein a thickness of the center portion of the second induction target part is less than that of the peripheral portion of the second induction target part such that a thickness of a portion between the center portion and the peripheral portion of the second induction target part gradually decreases or the thickness of the center portion of the second induction target part is greater than that of the peripheral portion of the second induction target part such that the thickness of the portion between the center portion and the peripheral portion of the second induction target part gradually increases;

an induction heating device configured to heat at least the plurality of first induction target parts and the second induction target part, which are provided in the reaction vessel and held by the induction target part holder by using an induction heating method.

[Supplementary Note 3]

According to another embodiment of the present invention, there is provided a method of manufacturing a semiconductor device, the method including: loading into a reaction vessel an induction target part holder holding a plurality of first induction target parts, which have a predetermined distance therebetween in an extending direction of the reaction vessel, and a second induction target part, each of the plurality of first induction target parts accommodating a substrate at a center portion thereof, wherein a thickness of the center portion of each of the plurality of first induction target parts is less than that of a peripheral portion of each of the plurality of first induction target parts, and a thickness of a center portion of the second induction target part is equal to or greater than that of a peripheral portion of the second first induction target part, the second induction target part being disposed at a predetermined distance from an uppermost first induction target part or a lowermost first induction target part among the plurality of first induction target parts in the extending direction; and heating the substrate accommodated on the first induction target part by heating at least the first and second induction target parts, which are held in the reaction vessel by the induction target part holder, using an induction heating device.

[Supplementary Note 4]

In the substrate processing apparatus of Supplementary Note 1, the thickness of the peripheral portion of the second induction target part is preferably greater than that of the peripheral portion of the first induction target part.

[Supplementary Note 5]

In the substrate processing apparatus of Supplementary Note 1, the thickness of the center portion of the second induction target part is greater than that of the peripheral portion of the second induction target part such that an outer diameter of a portion between the center portion and the peripheral portion of the second induction target part is equal to or greater than an inner diameter of a portion between the center portion and the peripheral portion of the first induction target part.

[Supplementary Note 6]

In the substrate processing apparatus of Supplementary Note 1, the thickness of the center portion of the second induction target part is greater than that of the peripheral portion of the second induction target part such that an outer diameter of a portion between the center portion and the peripheral portion of the second induction target part is less than an inner diameter of a portion between the center portion and the peripheral portion of the first induction target part.

[Supplementary Note 7]

In the substrate processing apparatus of Supplementary Note 2, the thickness of the center portion of the second induction target part is greater than that of the peripheral portion of the second induction target part such that an outer diameter of a portion between the center portion and the peripheral portion of the second induction target part is equal to or greater than an inner diameter of a portion between the center portion and the peripheral portion of the first induction target part.

[Supplementary Note 8]

In the substrate processing apparatus of Supplementary Note 2, the thickness of the center portion of the second induction target part is greater than that of the peripheral portion of the second induction target part such that an outer diameter of a portion between the center portion and the peripheral portion of the second induction target part is less than an inner diameter of a portion between the center portion and the peripheral portion of the first induction target part.

[Supplementary Note 9]

According to another embodiment of the present invention, there is provided a substrate processing apparatus comprising:

a reaction vessel configured to process a substrate therein;

a first induction target part including a peripheral portion and a center portion wherein a thickness of the center portion is less than that of the peripheral portion, the first induction target part being configured to heat the substrate accommodated on the center portion;

a second induction target part including a peripheral portion and a center portion wherein a thickness of the center portion is equal to or greater than that of the peripheral portion, the second induction target part being configured to heat the substrate accommodated on the center portion of the first induction target part;

an induction target part holder configured to hold the first induction target part and the second induction target part in a manner that the second induction part is spaced apart from the first induction target part by a predetermined distance; and

an induction heating device configured to heat at least the first and second induction target parts, which are provided in the reaction vessel and held by the induction target part holder, by using an induction heating method.

[Supplementary Note 10]

According to another embodiment of the present invention, there is provided a substrate processing apparatus comprising:

a reaction vessel configured to process a substrate therein;

a first induction target part comprising a peripheral portion and a center portion thinner than the peripheral portion, the first induction target part being configured to heat the substrate accommodated on the center portion;

a second induction target part including a peripheral portion and a center portion wherein a thickness of the center portion of the second induction target part is less than that of the peripheral portion of the second induction target part such that a thickness of a portion between the center portion and the peripheral portion of the second induction target part gradually decreases or the thickness of the center portion of the second induction target part is greater than that of the peripheral portion of the second induction target part such that the thickness of the portion between the center portion and the peripheral portion of the second induction target part gradually increases;

an induction target part holder configured to hold the first induction target part and the second induction target part in a manner that the second induction part is spaced apart from the first induction target part by a predetermined distance; and

an induction heating device configured to heat at least the first and second induction target parts, which are provided in the reaction vessel and held by the induction target part holder using an induction heating method.

[Supplementary Note 11]

According to another embodiment of the present invention, there is provided a method of manufacturing a semiconductor device, the method including: loading into a reaction vessel an induction target part holder holding a first induction target part and a second induction target part, the first induction target parts accommodating a substrate at a center portion thereof, wherein a thickness of the center portion of the first induction target parts is less than that of a peripheral portion of the first induction target parts, and a thickness of a center portion of the second induction target part is equal to or greater than that of a peripheral portion of the second first induction target part; and heating the substrate accommodated on the first induction target part by heating at least the first and second induction target parts, which are held in the reaction vessel by the induction target part holder, using an induction heating device.

What is claimed is:

1. A substrate processing apparatus comprising:
a reaction vessel configured to process substrates therein;
a first induction target part comprising a peripheral portion and a center portion wherein a thickness of the center portion is less than that of the peripheral portion, the first induction target part being configured to heat the substrate accommodated on the center portion;
a second induction target part comprising a peripheral portion and a center portion wherein a thickness of the center portion is equal to or greater than that of the peripheral portion, the second induction target part being configured to heat the substrate accommodated on the center portion of the first induction target part;
an induction target part holder configured to hold the first induction target part and the second induction target part in a manner that the second induction part is spaced apart from the first induction target part by a predetermined distance; and
an induction heating device configured to heat at least the first and second induction target parts which are provided in the reaction vessel and held by the induction target part holder, by using an induction heating method.

2. The substrate processing apparatus of claim 1, wherein the thickness of the peripheral portion of the second induction target part is greater than that of the peripheral portion of the first induction target part.

3. The substrate processing apparatus of claim 1, wherein the thickness of the center portion of the second induction target part is equal to or greater than that of the peripheral portion of the second induction target part such that an outer diameter of a portion between the center portion and the peripheral portion of the second induction target part is equal to or greater than an inner diameter of a portion between the center portion and the peripheral portion of the first induction target part.

4. The substrate processing apparatus of claim 1, wherein the thickness of the center portion of the second induction target part is greater than that of the peripheral portion of the second induction target part such that an outer diameter of a portion between the center portion and the peripheral portion of the second induction target part is less than an inner diameter of a portion between the center portion and the peripheral portion of the first induction target part.

5. The substrate processing apparatus of claim 1, wherein the first induction target part and the second induction target part are made of a same material.

6. The substrate processing apparatus of claim 1, wherein the second induction target part is disposed above an uppermost first induction target part among a plurality of the first induction target part held by the induction target part holder or below a lowermost first induction target part among the plurality of first induction target part held by the induction target part holder.

7. The substrate processing apparatus of claim 1, wherein a plurality of the second induction target part is disposed above an uppermost first induction target part among a plurality of the first induction target part held by the induction target part holder or below a lowermost first induction target part among the plurality of first induction target part held by the induction target part holder.

8. A substrate processing apparatus comprising:
a reaction vessel configured to process substrates therein;
a first induction target part comprising a peripheral portion and a center portion wherein a thickness of the center portion is less than that of the peripheral portion, the first induction target part being configured to heat the substrate accommodated on the center portion;
a second induction target part comprising a peripheral portion and a center portion wherein a thickness of the center portion is less than that of the peripheral portion such that a thickness of a portion between the center portion and the peripheral portion of the second induction target part gradually decreases, or the thickness of the center portion is greater than that of the peripheral portion such that the thickness of the portion between the center portion and the peripheral portion of the second induction target part gradually increases, the second induction target part being configured to heat the substrate accommodated on the center portion of the first induction target part; and
an induction target part holder configured to hold the first induction target part and the second induction target part in a manner that the second induction part is spaced apart from the first induction target part by a predetermined distance; and
an induction heating device configured to heat at least the first and second induction target parts which are provided in the reaction vessel and held by the induction target part holder, by using an induction heating method.

9. The substrate processing apparatus of claim 8, wherein the thickness of the center portion of the second induction target part is equal to or greater than that of the peripheral portion of the second induction target part such that an outer diameter of the portion between the center portion and the peripheral portion of the second induction target part is equal to or greater than an inner diameter of the portion between the center portion and the peripheral portion of the second induction target part.

10. The substrate processing apparatus of claim 8, wherein the thickness of the center portion of the second induction target part is equal to or greater than that of the peripheral portion of the second induction target part such that an outer diameter of the portion between the center portion and the peripheral portion of the second induction target part is less than an inner diameter of the portion between the center portion and the peripheral portion of the second induction target part.

11. The substrate processing apparatus of claim 8, wherein the second induction target part is disposed above an uppermost first induction target part among a plurality of the first induction target part held by the induction target part holder or below a lowermost first induction target part among the plurality of first induction target part held by the induction target part holder.

12. The substrate processing apparatus of claim 8, wherein a plurality of the second induction target part is disposed above an uppermost first induction target part among a plurality of the first induction target part held by the induction target part holder or below a lowermost first induction target part among the plurality of first induction target part held by the induction target part holder.

13. A method of manufacturing a semiconductor device, the method comprising:
loading an induction target part holder holding a first induction target part and a second induction target part into a reaction vessel, the first induction target part configured to heat a substrate accommodated on a center portion thereof and a thickness of the center portion of the first induction target part being less than that of a peripheral portion of the first induction target part, wherein the induction target part holder holds the first induction target part and the second induction target part in a manner that the second induction part is spaced apart from the first induction target part by a predetermined distance; and
heating the substrate accommodated on the first induction target part by heating at least the first and second induction target parts which are held in the reaction vessel by the induction target part holder using an induction heating device.
